(19) United States
(12) Patent Application Publication
(10) Pub. No.: US 2026/0211290 A1
(43) Pub. Date: Jul. 23, 2026

(54) DISPLAY SUBSTRATE AND METHOD OF MANUFACTURING THE SAME, AND DISPLAY DEVICE

(71) Applicant: Beijing Shiyan Technology Co., Ltd., Beijing (CN)

(72) Inventors: Lizhen ZHANG, Beijing (CN); Fuqiang LI, Beijing (CN); Changfeng LI, Beijing (CN); Hongrun WANG, Beijing (CN); Zhongyuan WU, Beijing (CN)

(21) Appl. No.: 18/718,752

(22) PCT Filed: Aug. 28, 2023
(86) PCT No.: PCT/CN2023/115198

§ 371 Date: Jun. 11, 2024

(30) Foreign Application Priority Data
Feb. 1, 2023 (CN) 202310126238.8

(51) Int. Cl. G02F 1/1362; G02F 1/1368; H10D 86/01; H10D 86/40; H10D 86/60

(52) U.S. Cl. CPC G02F 1/13624; G02F 1/136209; G02F 1/136227; G02F 1/136277; G02F 1/136295; G02F 1/1368; H10D 86/0221; H10D 86/443; H10D 86/60

(57) ABSTRACT

A display substrate and a method of manufacturing the same, and a display device are provided. The display substrate includes: a base substrate; a plurality of sub-pixels disposed on the base substrate, where the plurality of sub-pixels are arranged in an array along a first direction and a second directions on the base substrate, and at least one sub-pixel includes a first electrode; a first transistor and a second transistor which are disposed on the base substrate, where the first transistor includes an active layer and a gate, the active layer of the first transistor includes a channel region, a first electrode region and a second electrode region, and the second transistor includes an active layer, a gate, a first electrode and a second electrode; and a data line disposed on the base substrate, where the data line extends in the second direction on the base substrate.

### CROSS-REFERENCE TO RELATED APPLICATION(S)

This application is a Section 371 National Stage Application of International Application No. PCT/CN2023/115198, filed on Aug. 28, 2023, entitled “DISPLAY SUBSTRATE AND METHOD OF MANUFACTURING THE SAME, AND DISPLAY DEVICE”, which claims priority to Chinese Application No. 202310126238.8, filed on Feb. 1, 2023, the contents of which are incorporated herein by reference in their entireties.

### TECHNICAL FIELD

The present disclosure relates to a field of display technology, in particular to a display substrate and a method of manufacturing the same, and a display device.

### BACKGROUND

With a rapid development of display manufacturing technology, various display panels have gradually emerged in the field of display technology. Low temperature polycrystalline oxide (LTPO) substrate is a new type of display panel, which has the advantages of low temperature poly-silicon (LTPS) panel and oxide panel, and is one of the main development directions of future display panels. For display scenes such as VR (Virtual Reality) and 3D (three-dimensional), high resolution display panels play a crucial role.

### SUMMARY

In order to solve at least one aspect of the aforementioned problems, embodiments of the present disclosure provides a display substrate and a method of manufacturing the same, and a display device including the display substrate.

According to an aspect of the present disclosure, a display substrate is provided, including:
a base substrate;
a plurality of sub-pixels disposed on the base substrate, where the plurality of sub-pixels are arranged in an array along a first direction and a second direction on the base substrate, and at least one of the plurality of sub-pixels includes a first electrode;
a first transistor and a second transistor which are disposed on the base substrate, where the first transistor includes an active layer and a gate, the active layer of the first transistor includes a channel region, a first electrode region and a second electrode region, and the second transistor includes an active layer, a gate, a first electrode and a second electrode; and
a data line disposed on the base substrate, where the data line extends in the second direction on the base substrate,
where the display substrate includes: a first semiconductor layer located on the base substrate; a first conductive layer located on a side of the first semiconductor layer away from the base substrate; a second conductive layer located on a side of the first conductive layer away from the base substrate; a second semiconductor layer located on a side of the second conductive layer away from the base substrate; a third conductive layer located on a side of the second semiconductor layer away from the base substrate; a fourth conductive layer located on a side of the third conductive layer away from the base substrate;
the active layer of the second transistor is located in the first semiconductor layer, the gate of the second transistor is located in the first conductive layer, and the first electrode of the second transistor and the second electrode of the second transistor are located in the second conductive layer; the active layer of the first transistor is located in the second semiconductor layer, and the gate of the first transistor is located in the third conductive layer; and the first electrode of the sub-pixel is located in the fourth conductive layer; and
the data line is located in one of the first conductive layer and the second conductive layer, the first electrode region of the active layer of the first transistor is electrically connected to the data line, and the first electrode of the sub-pixel is electrically connected to the second electrode region of the active layer of the first transistor.

For example, the display substrate further includes a light shielding portion, where an orthographic projection of the light shielding portion on the base substrate at least partially overlaps with the channel region of the active layer of the first transistor, and the light shielding portion is located in one of the first conductive layer and the second conductive layer.

For example, the data line and the light shielding portion are located in different conductive layers.

For example, the orthographic projection of the light shielding portion on the base substrate partially overlaps with an orthographic projection of the data line on the base substrate.

For example, a plurality of light shielding portions of a row of sub-pixels arranged along the first direction are connected to each other, to form a light shielding strip extending along the first direction, and an orthographic projection of the light shielding strip on the base substrate intersects with the orthographic projection of the data line on the base substrate.

For example, the data line and the light shielding portion are located in a same conductive layer.

For example, the light shielding portion is connected to the data line, and the light shielding portion protrudes along the first direction from the data line.

For example, the display substrate further includes a dummy data line disposed on the base substrate, the dummy data line extends along the second direction on the base substrate, and the data line and the dummy data line are alternately disposed in the first direction; and the light shielding portion is connected to the dummy data line, and the light shielding portion protrudes along the first direction from the dummy data line.

For example, two adjacent columns of sub-pixels share one dummy data line; and for the two adjacent columns of sub-pixels located on two sides of the same dummy data line, light shielding portions of the two adjacent columns of sub-pixels are connected to the same dummy data line.

For example, the first electrode region of the active layer of the first transistor is electrically connected to the data line through a lap joint portion.

For example, the lap joint portion is located in the third conductive layer.

For example, the display substrate further includes a gate line disposed on the base substrate, the gate line extends in the first direction, and an orthographic projection of a part of the gate line on the base substrate overlaps with an orthographic projection of the active layer of the first transistor on the base substrate, so as to form the gate of the first transistor; and
an orthographic projection of the lap joint portion on the base substrate and an orthographic projection of the gate line on the base substrate are spaced apart from each other in the second direction.

For example, the lap joint portion includes a transparent conductive material.

For example, the display substrate includes: a first insulation layer disposed between the second semiconductor layer and the fourth conductive layer; and a first via hole passing through the first insulation layer; and
the first electrode of the sub-pixel is electrically connected to the second electrode region of the active layer of the first transistor through the first via hole.

For example, the display substrate includes: a fifth conductive layer disposed between the third conductive layer and the fourth conductive layer; and a conductive transfer portion located in the fifth conductive layer; and
the first electrode of the sub-pixel is electrically connected to the second electrode region of the active layer of the first transistor through the conductive transfer portion.

For example, the display substrate includes: a first sub-insulation layer disposed between the second semiconductor layer and the fifth conductive layer; a second sub-insulation layer disposed between the fifth conductive layer and the fourth conductive layer; a second via hole passing through the first sub-insulation layer; and a third via hole passing through the second sub-insulation layer; and
the first electrode of the sub-pixel is electrically connected to the second electrode region of the active layer of the first transistor through the third via hole, the conductive transfer portion and the second via hole.

For example, an orthographic projection of the third via hole on the base substrate falls within the orthographic projection of the light shielding portion on the base substrate.

For example, the orthographic projection of the second via hole on the base substrate and the orthographic projection of the third via hole on the base substrate are spaced apart from each other.

For example, the lap joint portion and the conductive transfer portion are located in the fifth conductive layer.

For example, the lap joint portion and the first electrode of the sub-pixel are located in the fourth conductive layer.

For example, the display substrate further includes: a second insulation layer located between a conductive layer in which the data line is located and the second semiconductor layer; a fourth via hole passing through the second insulation layer; and the first electrode region of the active layer of the first transistor is directly in contact with the data line through the fourth via hole.

For example, the display substrate further includes a gate line disposed on the base substrate, the gate line extends in the first direction, and an orthographic projection of a part of the gate line on the base substrate overlaps with an orthographic projection of the active layer of the first transistor on the base substrate; and
an orthographic projection of the fourth via hole on the base substrate at least partially overlaps with an orthographic projection of the gate line on the base substrate.

For example, the active layer of the first transistor includes a metal oxide semiconductor material; and/or, the active layer of the second transistor includes a low temperature poly-silicon semiconductor material.

For example, at least one sub-pixel further includes a second electrode, the first electrode of the sub-pixel is one of a pixel electrode and a common electrode, and the second electrode of the sub-pixel is the other one of the pixel electrode and the common electrode.

For example, the first electrode of the sub-pixel includes a transparent conductive material.

For example, the conductive transfer portion includes a transparent conductive material.

According to another aspect of the present disclosure, there is further provided a display substrate including:
a base substrate;
a plurality of sub-pixels disposed on the base substrate, where the plurality of sub-pixels are arranged in an array along a first direction and a second direction on the base substrate, and at least one of the plurality of sub-pixels includes a first electrode;
a first transistor and a second transistor which are disposed on the base substrate, where the first transistor includes an active layer and a gate, the active layer of the first transistor includes a channel region, a first electrode region and a second electrode region, and the second transistor includes an active layer, a gate, a first electrode and a second electrode; and
a data line disposed on the base substrate, where the data line extends along the second direction on the base substrate,
where the display substrate includes: a first semiconductor layer located on the base substrate; a first conductive layer located on a side of the first semiconductor layer away from the base substrate; a second semiconductor layer located on a side of the first conductive layer away from the base substrate; a second conductive layer located on a side of the second semiconductor layer away from the base substrate; and a third conductive layer located on a side of the second conductive layer away from the base substrate;
the active layer of the second transistor is located in the first semiconductor layer, the gate of the second transistor is located in the first conductive layer, and the first electrode of the second transistor and the second electrode of the second transistor are located in the second conductive layer; the active layer of the first transistor is located in the second semiconductor layer, and the gate of the first transistor is located in the second conductive layer; and the first electrode of the sub-pixel is located in the third conductive layer; and
the data line is located in the first conductive layer, the first electrode region of the active layer of the first transistor is electrically connected to the data line. and the first electrode of the sub-pixel is electrically connected to the second electrode region of the active layer of the first transistor.

For example, the display substrate further includes a light shielding portion, where an orthographic projection of the light shielding portion on the base substrate at least partially overlaps with the channel region of the active layer of the first transistor, and the light shielding portion and the data line are located in the first conductive layer.

For example, the light shielding portion is connected to the data line, and the light shielding portion protrudes along the first direction from the data line.

According to another aspect of the present disclosure, there is further provided a display device including a display substrate as described above.

According to another aspect of the present disclosure, there is further provided a method for manufacturing a display substrate, including:
providing a base substrate;
forming a first semiconductor material layer on the base substrate, and performing a patterning process on the first semiconductor material layer, so as to form an active layer of a second transistor;
forming a first conductive material layer on a side of the active layer of the second transistor away from the base substrate, and performing a patterning process on the first conductive material layer, so as to form a gate of the second transistor;
forming a second conductive material layer on a side of the gate of the second transistor away from the base substrate, and performing a patterning process on the second conductive material layer, so as to form a first electrode of the second transistor and a second electrode of the second transistor;
forming a second semiconductor material layer on a side of the first electrode and second electrode of the second transistor away from the base substrate, and performing a patterning process on the second semiconductor material layer, so as to form an active layer of a first transistor;
forming a first gate insulation material layer on a side of the active layer of the first transistor away from the base substrate;
forming a third conductive material layer on a side of the first gate insulation material layer away from the base substrate, and performing a patterning process on the third conductive material layer, so as to form a gate of the first transistor;
etching the first gate insulation material layer by using the gate of the first transistor as a mask, so as to form a first gate insulation layer;
conducting a part of the active layer of the first transistor which is not covered by the first gate insulation layer, so that the active layer of the first transistor includes a channel region, a first electrode region and a second electrode region; and
forming a fourth conductive material layer on a side of the gate of the first transistor away from the base substrate, and performing a patterning process on the fourth conductive material layer, so as to form a first electrode of the sub-pixel and a lap joint portion of the sub-pixel,
where the manufacturing method further includes forming a data line on the base substrate, one of the gate of the second transistor and the first electrode of the second transistor is formed by a same patterning process with the data line; and
the first electrode region of the active layer of the first transistor is electrically connected to the data line, and the first electrode of the sub-pixel is electrically connected to the second electrode region of the active layer of the first transistor.

### BRIEF DESCRIPTION OF THE DRAWINGS

Through the following description of embodiments of the present disclosure with reference to the accompanying drawings, the above contents, other purposes, features and advantages of the present disclosure will be clearer, in which:

FIG. 1 is a schematic plan view of a display substrate according to embodiments of the present disclosure;

FIG. 2 is a partial enlarged view of a part of a display substrate in a display region according to some exemplary embodiments of the present disclosure;

FIG. 3 is a cross-sectional view of a display substrate according to some exemplary embodiments of the present disclosure, in which the part located in the display region in FIG. 3 is a cross-sectional view taken along line AA′ in FIG. 2;

FIG. 4 is a schematic diagram of a structure of a display panel according to some exemplary embodiments of the present disclosure;

FIG. 5 is a cross-sectional view of a display substrate according to some other exemplary embodiments of the present disclosure;

FIG. 6 is a partial enlarged view of a part of a display substrate in a display region according to some other exemplary embodiments of the present disclosure;

FIG. 7 is a cross-sectional view of a display substrate according to some exemplary embodiments of the present disclosure, in which the part located in the display region in FIG. 7 is a cross-sectional view taken along line BB′ in FIG. 6;

FIG. 8 is a cross-sectional view of a display substrate according to some yet exemplary embodiments of the present disclosure, in which a light shielding portion and a data line are located in different layers;

FIG. 9 is a cross-sectional view of a display substrate according to some yet exemplary embodiments of the present disclosure, in which a lap joint portion is formed by a transparent conductive material;

FIG. 10 is a cross-sectional view of a display substrate according to some yet other exemplary embodiments of the present disclosure, in which a lap joint portion is formed by a transparent conductive material;

FIG. 11 is a partial enlarged view of a part of a display substrate in the display region according to some yet exemplary embodiments of the present disclosure;

FIG. 12 is a cross-sectional view of a display substrate according to some exemplary embodiments of the present disclosure, in which the part located in the display region in FIG. 12 is a cross-sectional view taken along line CC′ in FIG. 11;

FIG. 13 is a cross-sectional view of a display substrate according to some yet exemplary embodiments of the present disclosure, which schematically shows a variation relative to FIG. 12;

FIG. 14 is a cross-sectional view of a display substrate according to some still exemplary embodiments of the present disclosure, which schematically shows a variation relative to FIG. 12;

FIG. 15 is a cross-sectional view of a display substrate according to some still exemplary embodiments of the present disclosure, which schematically shows a variation relative to FIG. 13;

FIG. 16 is a cross-sectional view of a display substrate according to some still exemplary embodiments of the present disclosure, which schematically shows a lap joint portion and a first electrode located in a same layer;

FIG. 17 is a partial enlarged view of a part of a display substrate in the display region according to some yet exemplary embodiments of the present disclosure, which schematically shows an active layer of a first transistor directly electrically connected to a data line;

FIG. 18 is a cross-sectional view of a display substrate according to some exemplary embodiments of the present disclosure, in which the part located in the display region in FIG. 18 is a cross-sectional view taken along line DD′ in FIG. 17;

FIG. 19 is a cross-sectional view of a display substrate according to some still exemplary embodiments of the present disclosure, which schematically shows a data line and a light shielding portion located in a second conductive layer;

FIG. 20 is a partial enlarged view of a part of a display substrate in the display region according to some still exemplary embodiments of the present disclosure;

FIG. 21 is a partial enlarged view of a part of a display substrate in a display region according to some yet exemplary embodiments of the present disclosure, which schematically shows an active layer of a first transistor directly electrically connected to a data line, and the data line and a light shielding portion are located in different layers;

FIG. 22 is a cross-sectional view of a display substrate according to some exemplary embodiments of the present disclosure, where the part located in the display region in FIG. 22 is a cross-sectional view taken along line EE′ in FIG. 21;

FIG. 23 is a partial enlarged view of a part of a display substrate in the display region according to some yet exemplary embodiments of the present disclosure, which schematically shows an active layer of a first transistor directly electrically connected to a data line, the data line and a light shielding portion are located in different layers, and a conductive transfer portion is provided;

FIG. 24 is a cross-sectional view of a display substrate according to some exemplary embodiments of the present disclosure, where the part located in the display region in FIG. 24 is a cross-sectional view taken along line FF′ in FIG. 23;

FIG. 25 is a partial enlarged view of a part of a display substrate in a display region according to some yet exemplary embodiments of the present disclosure, which schematically shows the display substrate including a data line and a dummy data line;

FIG. 26 is a cross-sectional view of a display substrate according to some exemplary embodiments of the present disclosure, in which FIG. 26 is a cross-sectional view taken along line HH′ in FIG. 25;

FIG. 27 schematically shows a flowchart of a method of manufacturing a display substrate according to some exemplary embodiments of the present disclosure;

FIG. 28A to FIG. 28H schematically show cross-sectional views of a structure formed after some operations are performed in the method flowchart shown in FIG. 27;

FIG. 29 schematically shows a flowchart of a method of manufacturing a display substrate according to some other exemplary embodiments of the present disclosure;

FIG. 30A to FIG. 30I schematically show cross-sectional views of a structure formed after some operations are performed in the method flowchart shown in FIG. 29;

FIG. 31 schematically shows a flowchart of a method of manufacturing a display panel according to another embodiment of the present disclosure; and FIG. 32A to FIG. 32J schematically show diagrams of a structure formed after some operations are performed in the method flowchart shown in FIG. 31 according to embodiments of the present disclosure.

It should be noted that, for the sake of clarity, in the drawings used to describe the embodiments of the present disclosure, the sizes of layers, structures or areas may be enlarged or reduced, that is, these drawings are not drawn according to the actual scale.

### DETAILED DESCRIPTION OF EMBODIMENTS

In order to make purposes, technical solutions, and advantages of embodiments of the present disclosure clearer, technical solutions in some embodiments of the present disclosure will be described clearly and completely in combination with accompanying drawings. Obviously, the described embodiments are only part of the embodiments of the present disclosure, not all of them. Based on the embodiments of the present disclosure provided, all other embodiments obtained by those of ordinary skilled in the art without creative labor, fall within scope of protection of the present disclosure.

It should be noted that, in the drawings, a size and a relative size of the elements may be exaggerated for clarity and/or description. In this way, a dimension and a relative dimension of the various elements are not necessarily limited to those shown in the drawings. In the specification and drawings, a same or similar reference number refer to a same or similar part.

Unless otherwise defined, the technical or scientific terms used in the embodiments of the present disclosure shall have the usual meaning understood by those of ordinary skilled in the art. The terms “first”, “second”, and similar terms used in the embodiments of the present disclosure do not indicate any order, quantity, or importance, but are only used to distinguish different components. Words such as “comprise”, “include”, and similar terms means that components or objects listed before the word include components or objects listed after the word and their equivalents, rather than excluding other components or objects.

In this text, unless otherwise specified, directional terms such as “upper”, “lower”, “left”, “right”, “inside”, “outside” may be used herein to represent orientation or positional relationships based on the drawings, only for the purpose of describing the present disclosure, rather than indicating or implying that the device, element or component referred to must have a specific orientation, or must be constructed or operated in a specific orientation. It will be understood that when the absolute position of the described object changes, the relative positional relationship they represent may also change accordingly. Therefore, these directional terms may not be understood as restrictions on the present disclosure.

It should be noted that the expression “same layer” refers to a layer structure which is formed by forming a layer used to form a specific pattern by the same film-forming process, and then patterning the layer by using the same mask through one patterning process. According to the difference between the specific patterns, the patterning process may include multiple exposure, development or etching processes, and the specific pattern in the formed layer structure may be continuous or discontinuous. That is, multiple elements, components, structures and/or parts located in the “same layer” are made of the same material and formed by the same patterning process. Generally, multiple elements, components, structures and/or parts located in the “same layer” have substantially the same thicknesses.

Those skilled in the art will understand that in the present disclosure, unless otherwise specified, the expression “height” or “thickness” refers to a dimension of a surface of each film layer along a direction perpendicular to the display substrate, i.e., a dimension along a light exit direction of the display substrate, or referred to as a dimension along a normal direction of the display device.

In this text, directional expressions such as “first direction” and “second direction” are used to describe different directions along pixel units, such as a vertical direction of the pixel units and a horizontal direction of the pixel units, or a row direction of sub-pixel arrangements and a column direction of sub-pixel arrangements. It should be understood that such representation is only an illustrative description rather than a limitation on the present disclosure.

Transistors used in the embodiments of the present disclosure may be thin film transistors, field-effect transistors, or other devices with similar characteristics. Since a source of the thin film transistor is symmetrical to a drain of the thin film transistor used herein, its source and drain may be interchanged. In the embodiments of the present disclosure, the transistor may include a gate, a first electrode and a second electrode. The first electrode may represent one of the source and the drain, and the second electrode may represent the other one of the source and the drain. Correspondingly, an active layer of the transistor may include a channel region, a first electrode region and a second electrode region. The channel region is located between the first electrode region and the second electrode region. The first electrode region may be one of the source region and the drain region, and the second electrode region may be the other one of the source region and the drain region. In the following examples, a P-type thin film transistor used as a driving transistor may be mainly described, while other transistors have the same or different types relative to the driving transistor according to circuit design. Similarly, in other embodiments, the driving transistor may also be shown as an N-type thin film transistor.

In the embodiments of the present disclosure, an LTPO circuit may be used as a pixel driving circuit of a display substrate, that is, low-temperature poly-silicon (LTPS) technology and oxide (IGZO) technology are used to form an LTPO circuit. Low temperature poly-silicon thin film transistors have high electron mobility, fast reaction speed, and advantages such as high brightness, high resolution and low power consumption. Oxide thin film transistors, for example, use oxide semiconductors as an active layer of the TFT, such as indium gallium zinc oxide (abbreviated as IGZO). Oxide semiconductors have high electron mobility and good turn-off characteristics. Compared with LTPS, a process of manufacturing the oxide semiconductors is simple and has higher compatibility with a process of manufacturing amorphous silicon. Of course, the oxide thin film transistors may also be other metal oxide semiconductors, such as indium zinc tin oxide (IZTO) or indium gallium zinc tin oxide (IGZTO). It is possible to effectively reduce the size of the transistor and prevent leakage current by using the oxide thin film transistors, thereby causing the pixel circuit to be applied to low frequency driving while increasing the resolution of the display substrate.

In this text, the term “PPI” (Pixels Per Inch) represents pixel density, which represents a number of pixels disposed per inch. Generally, if the PPI value is higher, it represents that the display device may display images at a higher density.

In a display panel, high PPI (Pixels Per Inch, a density unit of a pixel, a number of pixels per inch) means a finer picture quality. However, an ability of human to distinguish lights is related to a minimum angle at which lights enter human eyes. The human eyes may recognize lights at an angle of 60 arc-seconds. In a case that a close distance of 10 cm is used, a recognizable PPI is about 871 PPI. However, for VR products, it is required to use specific small-sized panels in conjunction with optics for amplification, and at this time, higher PPI products are required. Therefore, it is a development trend that products with smaller TFTs and higher PPI are manufactured to meet the requirements of VR and other products.

In another aspect, the space we live in is a three-dimensional space, and most of human experiences come from the perception of depth information. Due to the presence of depth information, 3D display may achieve many functions that 2D displays do not have. Looking at most electronic products nowadays, many are still at the level of 2D display. This is related to the level of the previous level of image processing technology. With the development of technology, the image processing technology has advanced rapidly. The current image processing hardware has characteristics of miniaturization, efficiency and low heat generation. At the same time, various optical solutions for 3D display emerge one after another, laying a foundation for a popularization of 3D display technology. 3D display has become a display trend in the future, and existing 3D displays are substantially based on sacrificing resolution to achieve different content seen by the left eyes and the right eyes. Therefore, high resolution display panels have become a required condition for 3D display.

Based on this, high PPI products play a crucial role in cutting-edge displays such as VR and 3D display. In addition, in LCD (Liquid Crystal Display) products, high PPI display panels will further compress an opening rate. The gate and source drain conductive metals need good conductivity to reduce loading. Generally, non-transparent metals such as TiAITi/Mo and its alloys or Cu and its alloys are used as conductive metals, which will cause each pixel unit smaller and cause the opening rate lower.

In view of this, in the embodiments of the present disclosure, in order to improve the opening rate, LTPO technology is combined to make improvements in other regions as much as possible to increase the opening rate, while the horizontal or vertical pitch (periodic spacing) of a pixel unit is reduced to obtain a high PPI display panel.

Some exemplary embodiments of the present disclosure provide a display substrate. The display substrate includes: a base substrate; a plurality of pixel units disposed on the base substrate, where the plurality of sub-pixels are arranged in an array along a first direction and a second direction on the base substrate, and at least one pixel unit includes a first electrode; a first transistor and a second transistor which are disposed on the base substrate, where the first transistor includes an active layer and a gate, the active layer of the first transistor includes a channel region, a first electrode region and a second electrode region, and the second transistor includes an active layer, a gate, a first electrode and a second electrode; and a data line disposed on the base substrate, where the data line extends in the second direction on the base substrate, where the display substrate includes: a first semiconductor layer located on the base substrate; a first conductive layer located on a side of the first semiconductor layer away from the base substrate; a second conductive layer located on a side of the first conductive layer away from the base substrate; a second semiconductor layer located on a side of the second conductive layer away from the base substrate; a third conductive layer located on a side of the second semiconductor layer away from the base substrate; a fourth conductive layer located on a side of the third conductive layer away from the base substrate; the active layer of the second transistor is located in the first semiconductor layer, the gate of the second transistor is located in the first conductive layer, and the first electrode of the second transistor and the second electrode of the second transistor are located in the second conductive layer; the active layer of the first transistor is located in the second semiconductor layer, and the gate of the first transistor is located in the third conductive layer; and the first electrode of the pixel unit is located in the fourth conductive layer; and the data line is located in one of the first conductive layer and the second conductive layer, a first electrode region of the active layer of the first transistor is electrically connected to the data line, and the first electrode of the pixel unit is electrically connected to a second electrode region of the active layer of the first transistor. In the embodiments of the present disclosure, the conductive layer in which the data line is located is on a side of the active layer of the first transistor close to the base substrate. Therefore, there is no interference from a film layer in which the data line is located between the first electrode and the active layer of the first transistor. When forming a via hole for electrically connecting the first electrode and the active layer of the first transistor, there is no need to consider the process deviation during drilling, which is beneficial for reducing the process difficulty. Moreover, if the film layer in which the data line is located is between the first electrode and the active layer of the first transistor, it is required to avoid the signal line such as the data line when drilling holes to prevent a short circuit. In this way, the left and right of the via hole need to be spaced at a certain distance from the signal line, thereby increasing the pixel size. In the embodiments of the present disclosure, there is no interference from the film layer in which the data line is located between the first electrode and the active layer of the first transistor. When forming a via hole connecting the active layer of the first electrode and the first transistor, there is no need to consider the process deviation during drilling, which is beneficial for reducing pixel size, thereby achieving a high PPI display substrate.

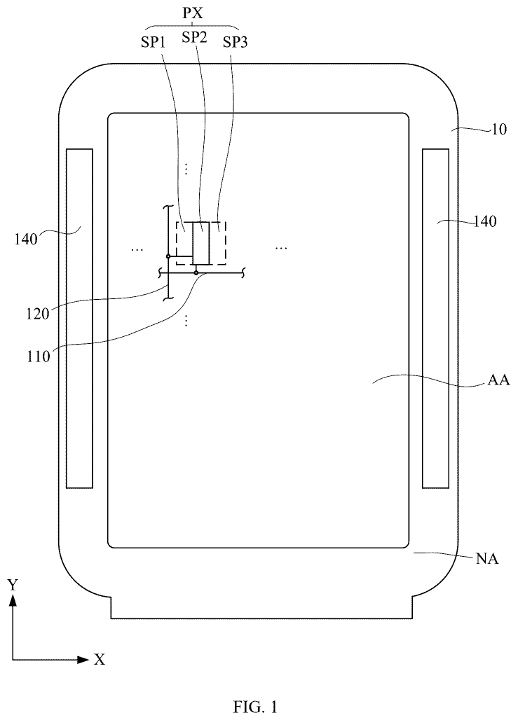

FIG. 1 is a schematic diagram view of a display substrate according to embodiments of the present disclosure. With reference to FIG. 1, the display substrate according to the embodiments of the present disclosure may include a base substrate 10 and a pixel unit PX disposed on the base substrate 10.

The display substrate may include a display region AA and a non-display region NA. The display region AA may be a region providing pixel units PX for displaying images. Each pixel unit PX will be described later. The non-display region NA is a region in which pixel units PX are not disposed, which may be a region where the image is not displayed. The non-display region NA corresponds to a border in a final display device, and a width of the border may be determined according to a width of the non-display region NA.

The display region AA may have various shapes. For example, the display region AA may be disposed in various shapes such as closed polygons (such as rectangles) including straight edges, circles, ellipses, etc. including curved edges, and semicircles, semi-ellipses, etc. including straight edges and curved edges. In the embodiments of the present disclosure, the display region AA is disposed as a region with a quadrilateral shape including straight edges. It should be understood that this is only an exemplary embodiment of the present disclosure and not a limitation of the present disclosure.

The non-display region NA may be disposed on at least one side of the display region AA. In the embodiments of the present disclosure, the non-display region NA may surround a periphery of the display region AA. In the embodiments of the present disclosure, the non-display region NA may include a horizontal portion extending in a first direction X and a vertical portion extending in a second direction Y.

The pixel unit PX is disposed in the display region AA. The pixel unit PX is the smallest unit used to display images, and a plurality of pixel units may be disposed.

A plurality of pixel units PX may be disposed and arranged in a matrix form along rows extending in the first direction X and columns extending in the first direction Y. However, the embodiments of the present disclosure do not specifically limit an arrangement form of the pixel units PX, and the pixel units PX may be arranged in various forms. For example, the pixel units PX may be arranged such that the direction inclined relative to the first direction X and the first direction Y becomes a column direction, and the direction intersecting with the column direction becomes a row direction.

That is to say, the plurality of pixel units PX are arranged in an array along the first direction X and the second direction Y, so as to form a plurality of rows of pixel units and a plurality of columns of pixel units.

A pixel unit PX may include a plurality of sub-pixels. For example, a pixel unit PX may include three sub-pixels, that is, a first sub-pixel SP1, a second sub-pixel SP2 and a third sub-pixel SP3. For example, the first sub-pixel SP1 may be a red sub-pixel, the second sub-pixel SP2 may be a green sub-pixel, and the third sub-pixel SP3 may be a blue sub-pixel.

It should be noted that in the embodiments of the present disclosure, there is no special limitation on a number of sub-pixels included in a pixel unit, and it is not limited to the three mentioned above.

For example, in the exemplary embodiment shown in FIG. 1, a gate line 110 and a data line 120 are schematically shown. That is, the display substrate may also include: a plurality of gate lines 110 and a plurality of data lines 120 which are disposed on the base substrate. The plurality of gate lines 110 provide scanning control signals to the plurality of rows of pixel units, respectively. The plurality of data lines 120 provide data signals to the plurality of columns of pixel units, respectively. The gate line 110 extends along the first direction X, and the plurality of gate lines 110 are spaced apart from each other along the second direction Y. The data line 120 extends along the second direction Y, and the plurality of data lines 120 are spaced apart from each other along the first direction X.

For example, the gate line 110 may be a representative of horizontal wiring, and the data line 120 may be a representative of vertical wiring. It should be understood that the horizontal wiring may also include other types of wiring or wiring used to supply other signals, and the vertical wiring may also include wiring of other types or wiring used to supply other signals.

With continued reference to FIG. 1, the display substrate may also include a driving circuit 140 located in the non-display region NA. For example, the driving circuit may be located on at least one side of the display region AA. In the embodiment shown in FIG. 1, the driving circuit 140 may be located on the left and right sides of the display region AA, respectively. It should be noted that the left and right sides may refer to the left and right sides of the display substrate (screen) viewed by the human eye during display. The driving circuit may be used to drive each pixel in the display substrate for display. For example, the driving circuit may include a gate driving circuit and a data driving circuit. The data driving circuit is used to sequentially lock the input data based on the clock signal timely, convert the locked data into analog signals, and input the signals to each data line 120 of the display substrate. The gate driving circuit is usually implemented by a shift register, and the shift register converts the clock signal into a turn-on/turn-off voltage and respectively outputs the voltage to each gate line 110 of the display substrate.

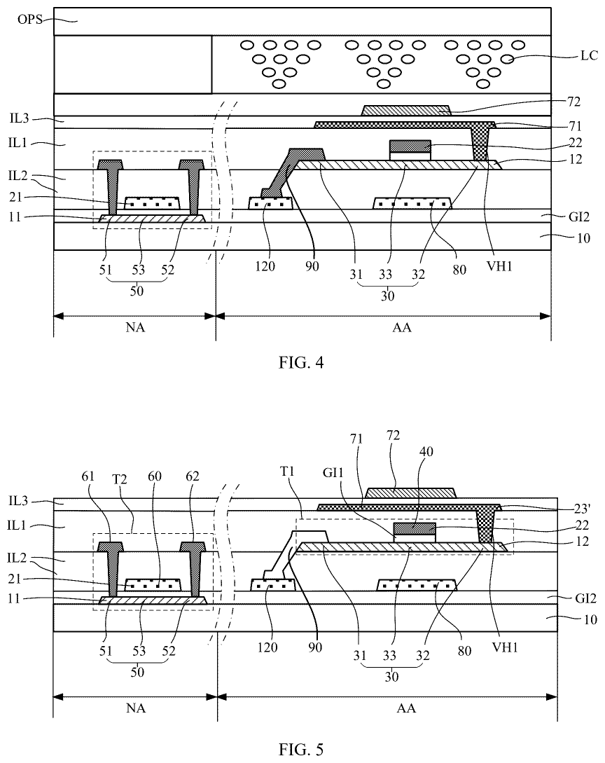

It should be noted that although the driving circuit shown in FIG. 4 is located on the left and right sides of the display region AA, the embodiments of the present disclosure are not limited to this, and the driving circuit may be located at any suitable position in the non-display region NA.

For example, the driving circuit may use GOA technology, that is, Gate Driver on Array. In GOA technology, the gate driving circuit is directly disposed on an array substrate, so as to replace an external driving chip. Each GOA unit serves as a stage of shift register, and each stage of shift register is connected to a gate line. Through outputting a turn-on voltage by the shift registers sequentially, a scanning of pixels row by row may be realized. In some embodiments, each stage of shift register may be connected to a plurality of gate lines. In this way, it may adapt to a development trend of high resolution and narrow border of the display substrate.

It should be noted that in the embodiments of the present disclosure, the display substrate may also include a pixel driving circuit located in the display region AA. For example, each sub-pixel SP1, SP2, and SP3 may have their own pixel driving circuit. The pixel driving circuit is used to control the display of each sub-pixel. In the embodiments of the present disclosure, a driving circuit (such as a gate driving circuit or a data driving circuit) located in the non-display region NA may include at least one transistor, and a pixel driving circuit located in the display region AA may include at least one transistor. In this text, for the convenience of description, at least one transistor included in the pixel driving circuit located in the display region AA is referred to as a first transistor, and at least one transistor included in the driving circuit located in the non-display region NA is referred to as a second transistor.

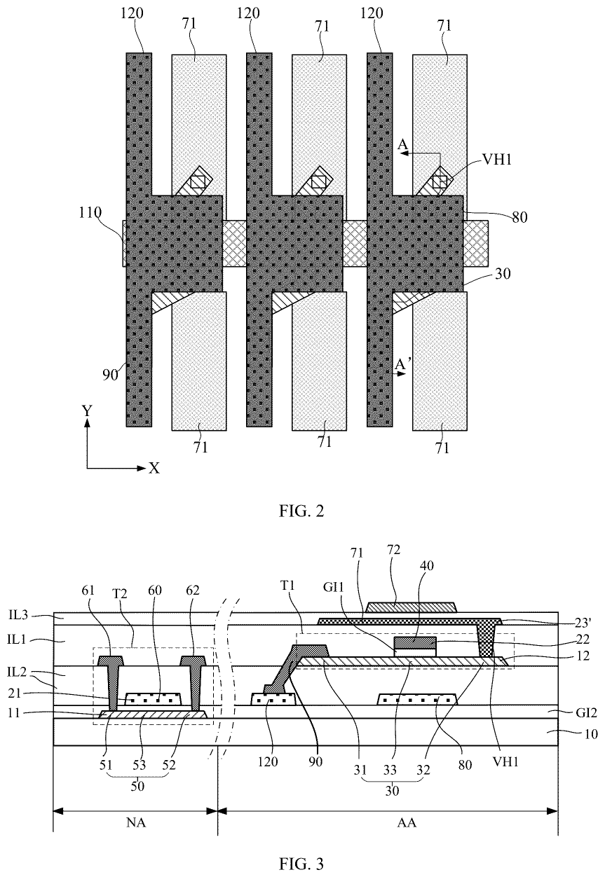

FIG. 2 is a partial enlarged view of a part of a display substrate in a display region according to some exemplary embodiments of the present disclosure. FIG. 3 is a cross-sectional view of a display substrate according to some exemplary embodiments of the present disclosure, in which the part located in the display region in FIG. 3 is a cross-sectional view taken along line AA′ in FIG. 2.

With reference to FIG. 2 and FIG. 3, the display substrate may include: a first semiconductor layer 11 located on the base substrate 10; a first conductive layer 21 located on a side of the first semiconductor layer 11 away from the base substrate; a second semiconductor layer 12 located on a side of the first conductive layer 21 away from the base substrate; a second conductive layer 22 located on a side of the second semiconductor layer 12 away from the base substrate; and a third conductive layer 23′ located on a side of the second conductive layer 22 away from the base substrate.

In the embodiments of the present disclosure, the display substrate may include a first transistor T1 and a second transistor T2 which are disposed on the base substrate 10. For example, as described above, the first transistor T1 may be at least one transistor included in the pixel driving circuit located in the display region AA, and the second transistor T2 may be at least one transistor included in the driving circuit located in the non-display region NA.

The first transistor T1 may include an active layer 30 and a gate 40. The active layer 30 of the first transistor includes a channel region 33, a first electrode region 31 and a second electrode region 32. The channel region 33 may be located between the first electrode region 31 and the second electrode region 32.

The second transistor T2 may include an active layer 50, a gate 60, a first electrode 61 and a second electrode 62. For example, the active layer 50 of the second transistor T2 may include a channel region 53, a first electrode region 51 and a second electrode region 52. The channel region 53 may be located between the first electrode region 51 and the second electrode region 52. The first electrode 61 may be electrically connected to the first electrode region 51 through a via hole, and the second electrode 62 may be electrically connected to the second electrode region 52 through a via hole.

In the embodiments of the present disclosure, the active layer 50 of the second transistor T2 is located in the first semiconductor layer 11, the gate 60 of the second transistor T2 is located in the first conductive layer 21, and the first electrode 61 of the second transistor T2 and the second electrode 62 of the second transistor T2 are located in the second conductive layer 22.

The active layer 30 of the first transistor T1 is located in the second semiconductor layer 12, and the gate 40 of the first transistor T1 is located in the second conductive layer 22.

For example, the first semiconductor layer 21 may include a low temperature poly-silicon material. For the first electrode region and the second electrode region, a conducting may be performed through doping or other means to achieve electrical connections of various structures. That is, in the embodiments of the present disclosure, the second transistor T2 may be a low temperature poly-silicon transistor, and the active layer 50 of the second transistor T2 includes a low temperature poly-silicon material. For example, the first electrode region 51 of the second transistor T2 and the second electrode region 52 of the second transistor T2 may be regions doped with p-type impurities. The low temperature poly-silicon material has high electron mobility, fast reaction speed, high brightness, high resolution and low power consumption, which is suitable for being applied to the GOA driving circuit.

For example, the second semiconductor layer 22 may include an oxide semiconductor material, such as indium gallium zinc oxide (IGZO), indium zinc tin oxide (IZTO), or indium gallium zinc tin oxide (IGZTO), etc. That is, in the embodiments of the present disclosure, the first transistor T1 may be an oxide semiconductor transistor, and the active layer 30 of the first transistor may include an oxide semiconductor material. For example, the first electrode region 31 of the first transistor T1 and the second electrode region 32 of the first transistor T1 may be regions doped with n-type impurities. It is possible to effectively reduce the size of transistors and prevent leakage current by using oxide thin film transistors. It is beneficial for reducing an occupied area of the pixel driving circuit, by applying oxide thin film transistors to the pixel driving circuit, thereby improving the opening rate of the display substrate and achieving the high PPI display substrate.

With reference to FIG. 1, FIG. 2 and FIG. 3, the display substrate may also include a data line 120 disposed on the base substrate 10, and the data line 120 extends in the second direction Y on the base substrate 10.

With continued reference to FIG. 2 and FIG. 3, the display substrate may also include a first electrode 71 and a second electrode 72. For example, the first electrode 71 may be one of a pixel electrode and a common electrode, and the second electrode 72 may be the other one of the pixel electrode and the common electrode.

In the embodiments of the present disclosure, the first electrode 71 may be located in the third conductive layer 23′, the data line 120 may be located in the first conductive layer 21, the first electrode region 31 of the active layer 30 of the first transistor T1 is electrically connected to the data line 120, and the first electrode 71 is electrically connected to the second electrode region 32 of the active layer 30 of the first transistor T1.

For example, the first conductive layer 21 may be a conductive layer formed by a gate material, such as Mo. For example, the second conductive layer 22 may be a conductive layer formed by a source and drain electrode material, such as Ti/Al/Ti. For example, the third conductive layer 23′ may be a conductive layer formed by a transparent conductive material, such as indium tin oxide (ITO), indium zinc oxide (IZO), etc.

With reference to FIG. 3, the display substrate may also include: a first insulation layer IL1 disposed between the second semiconductor layer 12 and the third conductive layer 23′; and a first via hole VH1 passing through the first insulation layer IL1. The first electrode 71 is electrically connected to the second electrode region 32 of the active layer 30 of the first transistor T1 through the first via hole VH1.

In the embodiments of the present disclosure, the conductive layer in which the data line 120 is located (i.e. the first conductive layer 21) is located on a side of the active layer 30 of the first transistor close to the base substrate. Therefore, there is no interference from a film layer in which the data line is located between the first electrode 71 and the active layer 30 of the first transistor. When forming a via hole (such as the first via hole VH1) electrically connecting the first electrode and the active layer of the first transistor, there is no need to consider the process deviation during drilling, which is beneficial for reducing process difficulty. Moreover, if the film layer in which the data line is located is between the first electrode and the active layer of the first transistor, it is required to avoid the signal line such as the data line when drilling holes to prevent a short circuit. In this way, the left and right of the via hole need to be spaced at a certain distance from the signal line, thereby increasing the pixel size. In the embodiments of the present disclosure, there is no interference from the film layer in which the data line is located between the first electrode 71 and the active layer 30 of the first transistor. When forming a via hole connecting the first electrode and the active layer of the first transistor, there is no need to consider the process deviation during drilling, which is beneficial for reducing pixel size, thereby achieving a high PPI display substrate.

With continued reference to FIG. 2 and FIG. 3, the display substrate may also include a light shielding portion 80. An orthographic projection of the light shielding portion 80 on the base substrate 10 at least partially overlaps with the channel region 32 of the active layer 30 of the first transistor T1. The light shielding portion 80 may protect the active layer 30 of the first transistor T1, and effectively make an improvement on the instability of a threshold voltage caused by light irradiation on the active layer 30 of the first transistor T1.

In the embodiments shown in FIG. 2 and FIG. 3, the light shielding portion 80 and the data line 120 are located in a same layer. For example, the light shielding portion 80 and the data line 120 are located in the first conductive layer 21. That is to say, in this embodiment, the gate 60 of the second transistor T2, the data line 120 and the light shielding portion 80 are located in the same layer. For example, the gate 60 of the second transistor T2, the data line 120 and the light shielding portion 80 located in the first conductive layer 21. In this way, in the process of manufacturing the display substrate, the gate 60 of the second transistor T2, the data line 120 and the light shielding portion 80 may be formed through the same patterning process, which is beneficial for reducing the number of patterning processes and the number of mask templates.

As shown in FIG. 2, for a column of sub-pixels, a data line 120 supplies data signals to the column of sub-pixels, and the light shielding portion 80 of the column of sub-pixels is connected to the data line 120. For example, the light shielding portion 80 of the column of sub-pixels is connected to the data line 120 as a whole. The light shielding portion 80 of the column of sub-pixels may protrude along the first direction X from the data line 120. For example, in the embodiment shown in FIG. 2, the light shielding portion 80 of the column of sub-pixels may protrude to the right side along the first direction X from the data line 120. In this embodiment, the light shielding portion 80 of a column of sub-pixels is connected to a data line 120 that supplies data signals to the column of sub-pixels, which is beneficial for simplifying a structure of a mask template and reducing a difficulty of the manufacturing process.

In this embodiment, the light shielding portion 80 of a column of sub-pixels and the data line 120 of an adjacent column of sub-pixels need to be spaced apart from each other, so as to avoid the data lines 120 of two columns of sub-pixels being electrically connected to each other through the light shielding portion 80.

FIG. 4 is a schematic diagram of a structure of a display panel according to some exemplary embodiments of the present disclosure. With reference to FIG. 4, the display substrate may also include a third insulation layer IL3 disposed between the film layer in which the first electrode 71 is located and the film layer in which the second electrode 72 is located. The display panel may include: a liquid crystal layer LC located on a side of the film layer in which the second electrode 72 is located away from the base substrate 10; and an opposite substrate OPS located on a side of the liquid crystal layer LC away from the base substrate 10.

For example, the first electrode 71 may be a pixel electrode, the second electrode 72 may be a common electrode. The first electrode 71 and the second electrode 72 are coordinated to form an electric field that drives the deflection of liquid crystal molecules in the liquid crystal layer LC, so as to achieve specific gray scale display.

In the embodiments of the present disclosure, the pixel electrode and the common electrode are disposed on the display substrate. For example, the display substrate may be an array substrate of a liquid crystal display panel. The liquid crystal display panel may be an ADS type display panel. It should be noted that the embodiments of the present disclosure are not limited to this, and the embodiments of the present disclosure may be applied to other types of display panels.

With reference back to FIG. 3, the display substrate may include a lap joint portion 90. The first electrode region 31 of the active layer 30 of the first transistor T1 is electrically connected to the data line 120 through the lap joint portion 90. In the embodiment shown in FIG. 3, the lap joint portion 90 is located in the second conductive layer 22, that is, the lap joint portion 90, the first electrode 61 and second electrode 62 of the second transistor T2 of the second transistor T2, and the gate 40 of the first transistor T1 may be located in the same layer. In this embodiment, the lap joint portion 90, the first electrode 61 and second electrode 62 of the second transistor T2 of the second transistor T2, and the gate 40 of the first transistor T1 may be formed through the same patterning process, which is beneficial for reducing the number of the patterning processes and reducing the number of mask templates.

FIG. 5 is a cross-sectional view of a display substrate according to some other exemplary embodiments of the present disclosure. It should be noted that in the following text, the difference between the embodiment shown in FIG. 5 and the embodiment shown in FIG. 3 will be mainly described. The same part may be referred to the previous description, which will not be repeated herein.

With reference to FIG. 5, the display substrate may include a lap joint portion 90, and the first electrode region 31 of the active layer 30 of the first transistor T1 is electrically connected to the data line 120 through the lap joint portion 90. In the embodiment shown in FIG. 5, the lap joint portion 90 includes a transparent conductive material, that is, the lap joint portion 90 is formed by a transparent conductive material.

For example, the elements, components or parts located in the first conductive layer 21 and the second conductive layer 22 are formed by metal conductive materials, and an area of their orthographic projections on the base substrate 10 corresponds to an area of an opaque region of the pixel unit or the sub-pixel. In this embodiment, the lap joint portion 90 is formed by using the transparent conductive material, and it is possible to reduce the area of the opaque region of the pixel unit or the sub-pixel, which is beneficial for improving the opening rate of the pixel unit or the sub-pixel. In other words, when light is emitted from the backlight, not all light may pass through the display substrate. For example, in a sub-pixel or a pixel unit, a metal structure of the transistor, various metal electrodes and metal signal wiring may affect the transmission of light. Therefore, the effective transparent region in the pixel unit is the region that does not contain the aforementioned components. A ratio of an area of the effective transparent region to an area of the entire region of the pixel unit may be referred to as an opening rate. In this embodiment, the material of the lap joint portion is changed to the transparent conductive material, so that it is possible to complete conductive connections while transmit light, increasing the area of the effective transparent region, thereby improving the opening rate of the pixel unit and the entire opening rate of the display panel.

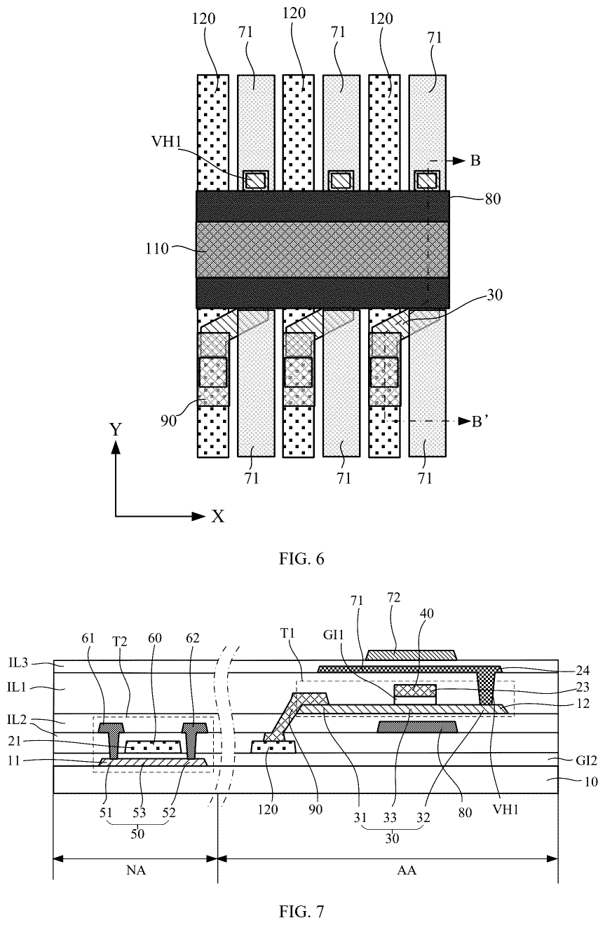

FIG. 6 is a partial enlarged view of a part of a display substrate in a display region according to some other exemplary embodiments of the present disclosure. FIG. 7 is a cross-sectional view of a display substrate according to some exemplary embodiments of the present disclosure, in which the part located in the display region in FIG. 7 is a cross-sectional view taken along line BB′ in FIG. 6.

With reference to FIG. 2 and FIG. 3, the display substrate may include: a first semiconductor layer 11 located on the base substrate 10; a first conductive layer 21 located on a side of the first semiconductor layer 11 away from the base substrate; a second conductive layer 22 located on a side of the first conductive layer 21 away from the base substrate; a second semiconductor layer 12 located on a side of the second conductive layer 22 away from the base substrate; a third conductive layer 23 located on a side of the second semiconductor layer 12 away from the base substrate; and a fourth conductive layer 24 located on a side of the third conductive layer 23 away from the base substrate.

In the embodiments of the present disclosure, the display substrate may include a first transistor T1 and a second transistor T2 which are disposed on the base substrate 10. For example, as described above, the first transistor T1 may be at least one transistor included in the pixel driving circuit located in the display region AA, and the second transistor T2 may be at least one transistor included in the driving circuit located in the non-display region NA.

The first transistor T1 may include an active layer 30 and a gate 40. The active layer 30 of the first transistor includes a channel region 33, a first electrode region 31 and a second electrode region 32. The channel region 33 may be located between the first electrode region 31 and the second electrode region 32.

The second transistor T2 may include an active layer 50, a gate 60, a first electrode 61 and a second electrode 62. For example, the active layer 50 of the second transistor T2 may include a channel region 53, a first electrode region 51 and a second electrode region 52. The channel region 53 may be located between the first electrode region 51 and the second electrode region 52. The first electrode 61 may be electrically connected to the first electrode region 51 through a via hole, and the second electrode 62 may be electrically connected to the second electrode region 52 through a via hole.

In the embodiments of the present disclosure, the active layer 50 of the second transistor T2 is located in the first semiconductor layer 11, the gate 60 of the second transistor T2 is located in the first conductive layer 21, and the first electrode 61 of the second transistor T2 and the second electrode 62 of the second transistor T2 are located in the second conductive layer 22.

The active layer 30 of the first transistor T1 is located in the second semiconductor layer 12, and the gate 40 of the first transistor T1 is located in the third conductive layer 23.

For example, the first semiconductor layer 21 may include low temperature poly-silicon material. For the first electrode region and the second electrode region, a conducting may be performed through doping or other means to achieve electrical connections of various structures. That is, in the embodiments of the present disclosure, the second transistor T2 may be a low temperature poly-silicon transistor, and the active layer 50 of the second transistor T2 includes a low temperature poly-silicon material. For example, the first electrode region 51 of the second transistor T2 and the second electrode region 52 of the second transistor T2 may be regions doped with p-type impurities. The low temperature poly-silicon material has high electron mobility, fast reaction speed, high brightness, high resolution and low power consumption, which is suitable for being applied to the GOA drive circuit.

For example, the second semiconductor layer 22 may include an oxide semiconductor material, such as indium gallium zinc oxide (IGZO), indium zinc tin oxide (IZTO), or indium gallium zinc tin oxide (IGZTO), etc. That is, in the embodiments of the present disclosure, the first transistor T1 may be an oxide semiconductor transistor, and the active layer 30 of the first transistor may include an oxide semiconductor material. For example, the first electrode region 31 of the first transistor T1 and the second electrode region 32 of the first transistor T1 may be regions doped with n-type impurities. It is possible to effectively reduce the size of transistors and prevent leakage current by using oxide thin film transistors. It is beneficial for reducing an occupied area of the pixel driving circuit, by applying oxide thin film transistors to the pixel driving circuit, thereby improving the opening rate of the display substrate and achieving the high PPI display substrate.

With reference to FIG. 1, FIG. 6 and FIG. 7, the display substrate may further include a data line 120 disposed on the base substrate 10, and the data line 120 extends in the second direction Y on the base substrate 10.

With continued reference to FIG. 6 and FIG. 7, the display substrate may also include a first electrode 71 and a second electrode 72. For example, the first electrode 71 may be one of a pixel electrode and a common electrode, and the second electrode 72 may be the other one of the pixel electrode and the common electrode. In the embodiments of the present disclosure, the first electrode 71 may be located in the fourth conductive layer 24.

The data line 120 may be located in one of the first conductive layer 21 and the second conductive layer 22. The first electrode region 31 of the active layer 30 of the first transistor T1 is electrically connected to the data line 120, and the first electrode 71 is electrically connected to the second electrode region 32 of the active layer 30 of the first transistor T1.

For example, the first conductive layer 21 and the third conductive layer 23 may be conductive layers formed by gate materials, such as Mo. For example, the second conductive layer 22 may be a conductive layer formed by a source and drain electrode material, such as Ti/Al/Ti. For example, the fourth conductive layer 24 may be a conductive layer formed by a transparent conductive material, such as indium tin oxide (ITO), indium zinc oxide (IZO), etc.

With reference to FIG. 7, the display substrate may also include: a first insulation layer IL1 disposed between the second semiconductor layer 12 and the fourth conductive layer 24; and a first via hole VH1 passing through the first insulation layer IL1. The first electrode 71 is electrically connected to the second electrode region 32 of the active layer 30 of the first transistor T1 through the first via hole VH1.

In the embodiments of the present disclosure, the conductive layer in which the data line 120 is located (i.e. the first conductive layer 21) is located on a side of the active layer 30 of the first transistor close to the base substrate. Therefore, there is no interference from a film layer in which the data line is located between the first electrode 71 and the active layer 30 of the first transistor. When forming a via hole (such as the first via hole VH1) electrically connecting the first electrode and the active layer of the first transistor, there is no need to consider the process deviation during drilling, which is beneficial for reducing process difficulty. Moreover, if the film layer in which the data line is located is between the first electrode and the active layer of the first transistor, it is required to avoid the signal line such as the data line when drilling holes to prevent a short circuit. In this way, the left and right of the via hole need to be spaced at a certain distance from the signal line, thereby increasing the pixel size. In the embodiments of the present disclosure, there is no interference from the film layer in which the data line is located between the first electrode 71 and the active layer 30 of the first transistor. When forming a via hole connecting the first electrode and the active layer of and the first transistor, there is no need to consider the process deviation during drilling, which is beneficial for reducing pixel size, thereby achieving a high PPI display substrate.

With continued reference to FIG. 6 and FIG. 7, the display substrate may also include a light shielding portion 80. An orthographic projection of the light shielding portion 80 on the base substrate 10 at least partially overlaps with the channel region 32 of the active layer 30 of the first transistor T1.

In the embodiments of the present disclosure, the light shielding portion 80 is located in one of the first conductive layer 21 and the second conductive layer 22. In the embodiments shown in FIG. 6 and FIG. 7, the data line 120 and the light shielding portion 80 are located in different conductive layers. For example, the data line 120 is located in the first conductive layer 21, and the light shielding portion 80 is located in the second conductive layer 22. That is to say, the data line 120 and the gate 60 of the second transistor T2 are located in a same layer, and the light shielding portion 80, the first electrode 61 of the second transistor and the second electrode 62 of the second transistor are located in a same layer.

In the embodiments of the present disclosure, the data line 120 and the light shielding portion 80 are disposed in different conductive layers. The light shielding portion 80 does not need to protrude from the data line 120 along the first direction X towards one side. In this way, it is possible to reduce the size of a single sub-pixel in the first direction X.

As shown in FIG. 6, the orthographic projection of the light shielding portion 80 on the base substrate 10 partially overlaps with an orthographic projection of the data line 120 on the base substrate 10.

For example, a plurality of light shielding portions 80 of a row of sub-pixels arranged along the first direction X are connected to each other, to form a light shielding strip extending along the first direction X. An orthographic projection of the light shielding strip on the base substrate 10 intersects with the orthographic projection of the data line 120 on the base substrate 10. That is to say, in the embodiments of the present disclosure, since the data line 120 and the light shielding portion 80 are disposed in different conductive layers, there is no need to dispose the light shielding portion of a column of sub-pixels and the data line of adjacent column of sub-pixels at intervals, which is beneficial for reducing the size of the sub-pixel in the first direction X. In this way, it is possible to reduce the horizontal pitch of the pixel unit.

It should be noted that the term “light shielding strip” refers to a strip-shaped component. For example, in this embodiment, the plurality of light shielding portions 80 are connected to each other to form a strip-shaped component that extends continuously along the first direction X, that is the aforementioned light shielding strip.

In this embodiment, the display substrate may include a lap joint portion 90. The first electrode region 31 of the active layer 30 of the first transistor T1 is electrically connected to the data line 120 through the lap joint portion 90. In the embodiment shown in FIG. 7, the lap joint portion 90 is located in the third conductive layer 23, that is, the lap joint portion 90 and the gate 40 of the first transistor T1 may be located in a same layer. In this embodiment, the lap joint portion 90 and the gate 40 of the first transistor T1 may be formed through the same patterning process, which is beneficial for reducing the number of patterning processes and the number of mask templates.

As shown in FIG. 6, the display substrate also includes a gate line 110 disposed on the base substrate 10. The gate line 110 extends along the first direction X. An orthographic projection of a part of the gate line 110 on the base substrate 10 overlaps with an orthographic projection of the active layer 30 of the first transistor T1 on the base substrate 10, so as to form the gate 40 of the first transistor T1.

For example, the gate line 110 and the light shielding strip extend along the first direction X. For a same row of sub-pixels, an orthographic projection of the gate line 110 of the row of sub-pixels on the base substrate 10 at least partially overlaps with an orthographic projection of the light shielding strip of the row of sub-pixels on the base substrate 10. For example, an orthographic projection of the part of the gate line 110 of the row of sub-pixels in the display region AA falls into the orthographic projection of the light shielding strip of the row of sub-pixels on the base substrate 10.

For example, an orthographic projection of the lap joint portion 90 on the base substrate 10 and the orthographic projection of the gate line 110 on the base substrate 10 are spaced apart from each other in the second direction Y. That is, the orthographic projection of the lap joint portion 90 on the base substrate 10 and the orthographic projection of the gate line 110 on the base substrate 10 in the second direction Y need to be spaced at a certain distance, so as to avoid an electrical connection between the lap joint portion 90 and the gate line 110.

It should be noted that at least one insulation layer may be disposed between any two adjacent layers among the semiconductor layer and the conductive layer mentioned above. The at least one insulation layer may include a structure of a single film layer or a structure of a plurality of film layers. For example, with reference back to FIG. 7, a second gate insulation layer GI2 may be disposed between the first semiconductor layer 11 and the first conductive layer 21. A part of the second insulation layer IL2 may be provided between the first conductive layer 21 and the second conductive layer 22. For example, a first interlayer dielectric layer may be provided. Another part of the second insulation layer IL2 may be provided between the second conductive layer 22 and the second semiconductor layer 12. For example, a second interlayer dielectric layer may be provided. A first gate insulation layer GI1 may be provided between the second semiconductor layer 12 and the third conductive layer 23. A first insulation layer IL1 may be provided between the third conductive layer 23 and the fourth conductive layer 24. For example, the first insulation layer IL1 may include a planarization layer, or the first insulation layer IL1 may include a planarization layer and a passivation layer. A third insulation layer IL3 may be disposed between the fourth conductive layer 24 and the conductive layer in which the second electrode 72 is located.

It should be noted that the above-mentioned insulation layers may use commonly used insulation materials in the display substrate, which will not be repeated herein.

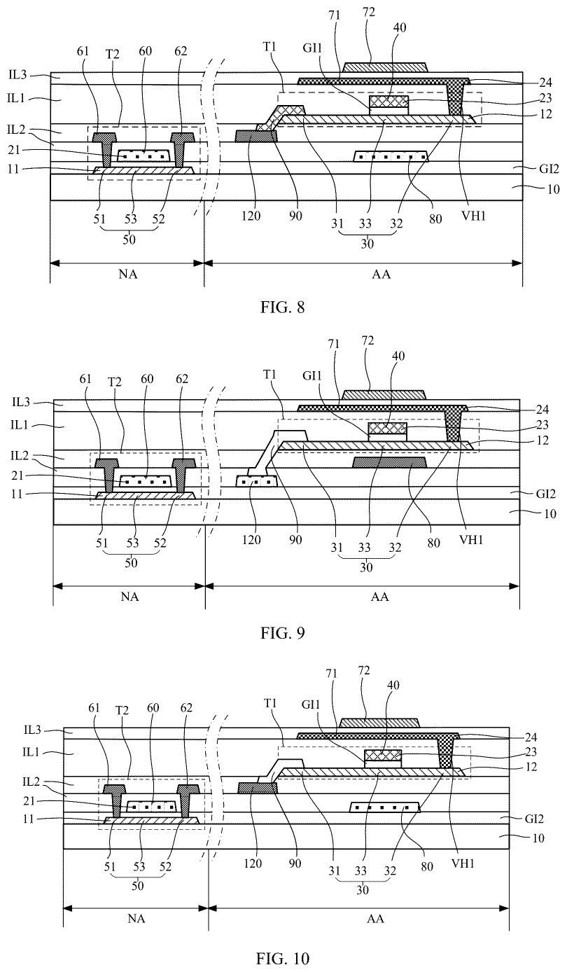

FIG. 8 is a cross-sectional view of a display substrate according to some yet exemplary embodiments of the present disclosure, in which a light shielding portion and a data line are located in different layers. It should be noted that in the following text, the difference between the embodiment shown in FIG. 8 and the embodiment shown in FIG. 7 will be mainly described. The same part may be referred to the previous description, which will not be repeated herein.

As shown in FIG. 8, the data line 120 and the light shielding portion 80 are located in different conductive layers. For example, the light shielding portion 80 is located in the first conductive layer 21, and the data line 120 is located in the second conductive layer 22. That is to say, the light shielding portion 80 and the gate 60 of the second transistor T2 are located in a same layer, and the data line 120, the first electrode 61 of the second transistor and the second electrode 62 of the second transistor are located in a same layer. Similarly, in this embodiment, the data line 120 and the light shielding portion 80 are disposed in different conductive layers, and the light shielding portion 80 does not need to protrude from the data line 120 along the first direction X towards one side. In this way, it is possible to reduce the size of a single sub-pixel in the first direction X.

FIG. 9 is a cross-sectional view of a display substrate according to some yet exemplary embodiments of the present disclosure, in which a lap joint portion is formed by a transparent conductive material. It should be noted that in the following text, the difference between the embodiment shown in FIG. 9 and the embodiment shown in FIG. 7 will be mainly described. The same part may be referred to the previous description, which will not be repeated herein.

As shown in FIG. 9, the data line 120 is located in the first conductive layer 21, and the light shielding portion 80 is located in the second conductive layer 22. That is to say, the data line 120 and the gate 60 of the second transistor T2 are located in a same layer, and the light shielding portion 80, the first electrode 61 of the second transistor and the second electrode 62 of the second transistor are located in a same layer. The display substrate may include a lap joint portion 90, and the first electrode region 31 of the active layer 30 of the first transistor T1 is electrically connected to the data line 120 through the lap joint portion 90. In the embodiment shown in FIG. 9, the lap joint portion 90 includes a transparent conductive material, that is, the lap joint portion 90 is formed by the transparent conductive material.

It should be understood that the elements, components or parts located in the first conductive layer 21 and the second conductive layer 22 are formed by metal conductive materials, and an area of their orthographic projections on the base substrate 10 corresponds to an area of an opaque region of the pixel unit or the sub-pixel. In this embodiment, the lap joint portion 90 is formed by using the transparent conductive material, and it is possible to reduce the area of the opaque region of the pixel unit or the sub-pixel, which is beneficial for improving the opening rate of the pixel unit or the sub-pixel.

FIG. 10 is a cross-sectional view of a display substrate according to some yet other exemplary embodiments of the present disclosure, in which a lap joint portion is formed by a transparent conductive material. It should be noted that in the following text, the differences between the embodiment shown in FIG. 10 and the embodiments shown in FIG. 7 and FIG. 8 will be mainly described. The same parts may refer to the previous description, which will not be repeated herein.

As shown in FIG. 10, the light shielding portion 80 is located in the first conductive layer 21, and the data line 120 is located in the second conductive layer 22. That is to say, the light shielding portion 80 and the gate 60 of the second transistor T2 are located in a same layer, and the data line 120, the first electrode 61 and second electrode 62 of the second transistor are located in a same layer. The display substrate may include a lap joint portion 90, and the first electrode region 31 of the active layer 30 of the first transistor T1 is electrically connected to the data line 120 through the lap joint portion 90. In the embodiment shown in FIG. 9, the lap joint portion 90 includes a transparent conductive material, that is, the lap joint portion 90 is formed by the transparent conductive material.

It should be understood that elements, components or parts located in the first conductive layer 21 and the second conductive layer 22 are formed by metal conductive materials, and an area of their orthographic projection on the base substrate 10 corresponds to an area of an opaque region of the pixel unit or the sub-pixel. In this embodiment, the lap joint portion 90 is formed by using the transparent conductive material, and it is possible to reduce the area of the opaque region of the pixel unit or the sub-pixel, which is beneficial for improving the opening rate of the pixel unit or the sub-pixel.

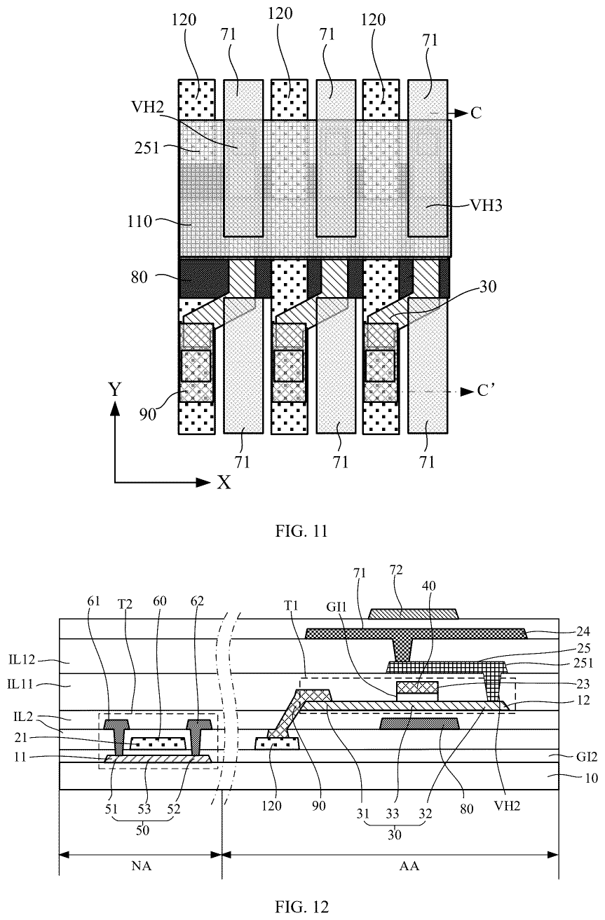

FIG. 11 is a partial enlarged view of a part of a display substrate in the display region according to some yet exemplary embodiments of the present disclosure. FIG. 12 is a cross-sectional view of a display substrate according to some exemplary embodiments of the present disclosure, in which the part located in the display region in FIG. 12 is a cross-sectional view taken along line CC′ in FIG. 11. It should be noted that in the following text, the differences between the embodiments shown in FIG. 11 and FIG. 12 and the embodiments shown in FIG. 2 to FIG. 10 will be mainly described. The same part may be referred to the previous description, which will not be repeated herein.

With reference to FIG. 11 and FIG. 12, the display substrate may include: a first semiconductor layer 11 located on the base substrate 10; a first conductive layer 21 located on a side of the first semiconductor layer 11 away from the base substrate; a second conductive layer 22 located on a side away from the base substrate of the first conductive layer 21; a second semiconductor layer 12 located on a side of the second conductive layer 22 away from the base substrate; a third conductive layer 23 located on a side of the second semiconductor layer 12 away from the base substrate; and a fourth conductive layer 24 located on a side of the third conductive layer 23 away from the base substrate.

As shown in FIG. 12, the display substrate may also include: a fifth conductive layer 25 disposed between the third conductive layer 23 and the fourth conductive layer 24; and a conductive transfer portion 251 located in the fifth conductive layer 25.

For example, the fifth conductive layer 25 may be a conductive layer formed by a transparent conductive material, such as indium tin oxide (ITO), indium zinc oxide (IZO), etc. That is, the conductive transfer portion 251 and the first electrode 71 include transparent conductive materials. In this embodiment, the conductive transfer portion 251 and the first electrode 71 are formed by the same conductive material, which is beneficial for reducing a contact resistance between the two, thereby improving the electrical connection ability between the two.

In the embodiments shown in FIG. 11 and FIG. 12, the first electrode 71 is electrically connected to the second electrode region 32 of the active layer of the first transistor T1 through a conductive transfer portion 251.

With continued reference to FIG. 12, the display substrate includes: a first sub-insulation layer IL11 disposed between the second semiconductor layer 12 and the fifth conductive layer 25; a second sub-insulation layer IL12 disposed between the fifth conductive layer 25 and the fourth conductive layer 24; a second via hole VH2 passing through the first sub-insulation layer IL11; and a third via hole VH3 passing through the second sub-insulation layer IL12. The first electrode 71 is electrically connected to the second electrode region 32 of the active layer of the first transistor T1 through the third via hole VH3, the conductive transfer portion 251 and the second via hole VH2.

In the embodiments of the present disclosure, an orthographic projection of the third via hole VH3 on the base substrate 10 falls into the orthographic projection of the light shielding portion 80 on the base substrate 10. That is to say, the third via hole VH3 passing through the second sub-insulation layer IL12 is located in a non-light-emitting region of the sub-pixel.

As shown in FIG. 11, in the embodiments of the present disclosure, an orthographic projection of the second via hole VH2 on the base substrate 10 and the orthographic projection of the third via hole VH3 on the base substrate 10 are spaced apart from each other. In this way, it is beneficial to avoid mutual influence between the second via hole and the third via hole.

For example, for a same sub-pixel, the orthographic projection of the second via hole VH2 on the base substrate 10 and the orthographic projection of the third via hole VH3 on the base substrate 10 are substantially aligned along the second direction Y. For example, for the same sub-pixel, a center of the orthographic projection of the second via hole VH2 on the base substrate 10 and a center of the orthographic projection of the third via hole VH3 on the base substrate 10 are located on a same vertical line extending along the second direction Y. In this way, it is beneficial to form the via hole through a patterning process.

It should be noted that each of the first sub-insulation layer IL11 and the second sub-insulation layer IL12 may include a single insulation film layer, or may include a plurality of insulation film layers. For example, the first sub-insulation layer IL11 may include a passivation layer, and the second sub-insulation layer IL12 may include a planarization layer. After the planarization of the second sub-insulation layer IL 12, a first electrode 71 of the sub-pixel is directly formed on an upper surface of the second sub-insulation layer IL12. The morphology of the upper surface of the second sub-insulation layer IL12 will affect the structure of the first electrode 71 formed on the upper surface of the second sub-insulation layer IL12.

Inventors found through research that the first sub-insulation layer IL11 is usually thin, and the second sub-insulation layer IL12 is usually thick, that is, a thickness of the second sub-insulation layer IL12 is greater than a thickness of the first sub-insulation layer IL11. In this case, the via hole formed in the second sub-insulation layer IL12 will affect the morphology of the upper surface of the second sub-insulation layer IL12. Specifically, the via hole formed in the second sub-insulation layer IL12 will cause a decrease of the planarization level of the upper surface of the second sub-insulation layer IL12 around the via hole. In this way, the structure of the first electrode 71 located above the via hole in the second insulation layer IL12 will be affected. Experimental research has found that this structural influence may cause local distortion of the electric field between the first electrode 71 and the second electrode 72, thereby reducing the control accuracy of liquid crystal molecules in the light-emitting region. Moreover, some regions around the via hole may not be used as the light-emitting regions, thereby reducing the opening rate of the sub-pixel.

In the embodiments shown in FIG. 11 and FIG. 12, by disposing the conductive transfer portion 251, the third via hole VH3 passing through the second sub-insulation layer IL12 may be disposed in the non-light-emitting region of the sub-pixel. In this way, even if the third via hole VH3 has an impact on the morphology of the upper surface of the second sub-insulation layer IL12, since the third via hole VH3 and its surrounding parts are located in the non-light-emitting region of the sub-pixel, this effect will not affect the control accuracy of the liquid crystal molecules in the light-emitting region, nor will it affect the opening rate of the sub-pixel.

It should be understood that due to the smaller thickness of the first sub-insulation layer IL11 compared to the second sub-insulation layer IL12, and a larger distance between the first sub-insulation layer IL11 and the upper surface of the second sub-insulation layer IL12, the second via hole VH2 formed in the first sub-insulation layer IL11 has a smaller impact on the morphology of the upper surface of the second sub-insulation layer IL12. That is to say, the second via hole VH2 in the first sub-insulation layer IL11 will not affect the control accuracy of the liquid crystal molecules in the light-emitting region, nor will it affect the opening rate of the sub-pixel.

In the embodiments of the present disclosure, by disposing the conductive transfer portion 251, the first electrode 71 is electrically connected to the second electrode region 32 of the active layer of the first transistor T1 through the third via hole VH3, the conductive transfer portion 251 and the second via hole VH2, so that it is possible to achieve high control accuracy of the liquid crystal molecules in the light-emitting region and high opening rate.

It should be noted that, in a case of no conflicting, the structures or features in the various embodiments of the present disclosure may be arbitrarily associated or combined to form a plurality of different embodiments. In the following embodiments, several association or combination methods are listed. It should be noted that the enumeration is not exhaustive, and the embodiments of the present disclosure may also include various other association or combination methods.

For example, in the embodiments shown in FIG. 11 and FIG. 12, the data line 120 is located in the first conductive layer 21, and the light shielding portion 80 is located in the second conductive layer 22. That is to say, the data line 120 and the gate 60 of the second transistor T2 are located in a same layer, and the light shielding portion 80, the first electrode 61 of the second transistor and the second electrode 62 of the second transistor are located in a same layer. The display substrate may include a lap joint portion 90, and the first electrode region 31 of the active layer 30 of the first transistor T1 is electrically connected to the data line 120 through the lap joint portion 90. For example, the lap joint portion 90 may be located in the same layer as the gate 40 of the first transistor T1.

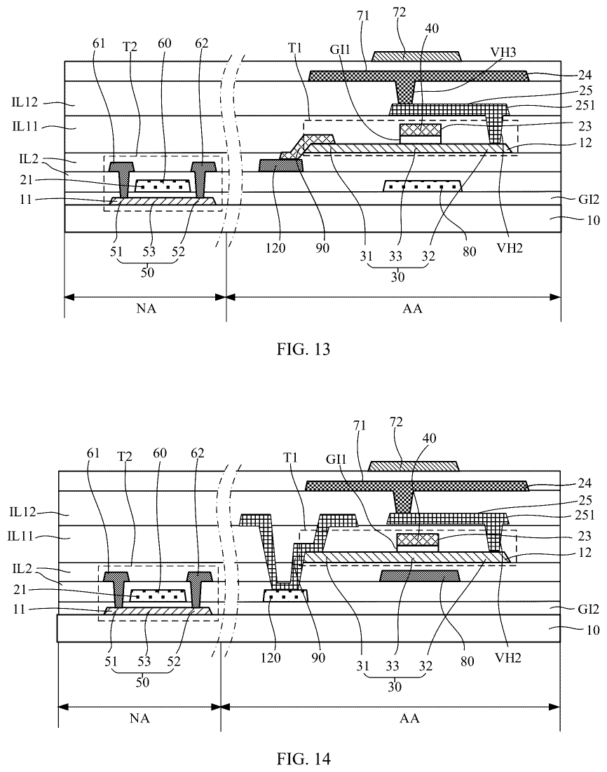

FIG. 13 is a cross-sectional view of a display substrate according to some yet exemplary embodiments of the present disclosure, which schematically shows a variation relative to FIG. 12. It should be noted that in the following text, the differences between the embodiment shown in FIG. 13 and those described above will be mainly described. The same part may be referred to the previous description, which will not be repeated herein.

As shown in FIG. 13, the data line 120 and the light shielding portion 80 are located in different conductive layers. For example, the light shielding portion 80 is located in the first conductive layer 21, and the data line 120 is located in the second conductive layer 22. That is to say, the light shielding portion 80 and the gate 60 of the second transistor T2 are located in a same layer, and the data line 120, the first electrode 61 of the second transistor and the second electrode 62 of the second transistor are located in a same layer.

The display substrate may include a lap joint portion 90, and the first electrode region 31 of the active layer 30 of the first transistor T1 is electrically connected to the data line 120 through the lap joint portion 90. For example, the lap joint portion 90 may be located in the same layer as the gate 40 of the first transistor T1.

FIG. 14 is a cross-sectional view of a display substrate according to some still exemplary embodiments of the present disclosure, which schematically shows a variation relative to FIG. 12. It should be noted that in the following text, the differences between the embodiments shown in FIG. 14 and those described above will be mainly described. The same part may refer to the previous description, which will not be repeated here.

For example, in the embodiment shown in FIG. 14, the data line 120 is located in the first conductive layer 21, and the light shielding portion 80 is located in the second conductive layer 22. That is to say, the data line 120 and the gate 60 of the second transistor T2 are located in a same layer, and the light shielding portion 80, the first electrode 61 the second transistor and the second electrode 62 of the second transistor are located in a same layer.

With continued reference to FIG. 14, the display substrate may include a lap joint portion 90, and the first electrode region 31 of the active layer 30 of the first transistor T1 is electrically connected to the data line 120 through the lap joint portion 90. The lap joint portion 90 may be located in the fifth conductive layer 25, that is, the lap joint portion 90 and the conductive transfer portion part 251 are located in a same layer. In this way, the lap joint portion 90 and the conductive transfer portion part 251 may be formed through the same patterning process, which is beneficial for reducing the number of patterning processes and the number of mask templates.

For example, in this embodiment, the lap joint portion 90 and the conductive transfer portion 251 located in the same layer are formed by transparent conductive materials. It is possible to increase the area of the effective light transmission region, thereby improving the opening rate of sub-pixel and the entire opening rate of the display panel.

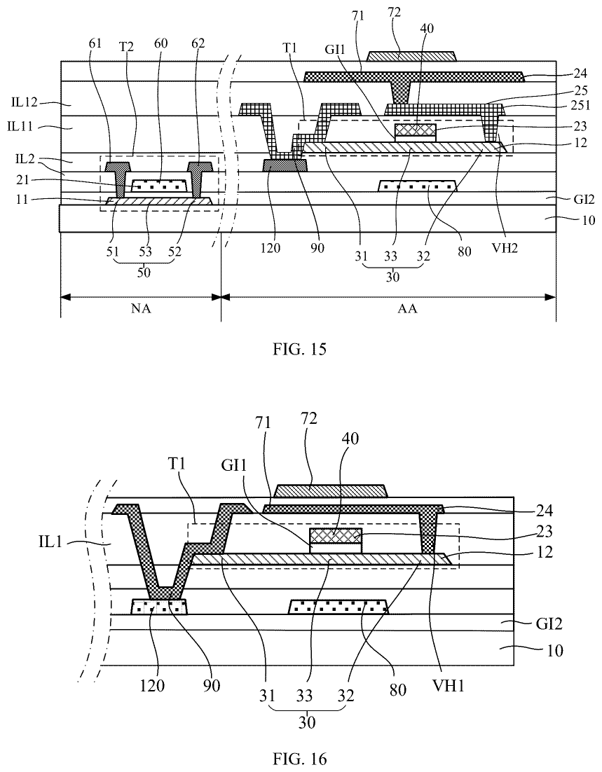

FIG. 15 is a cross-sectional view of a display substrate according to some still exemplary embodiments of the present disclosure, which schematically shows a variation relative to FIG. 13. It should be noted that in the following text, the main description will be the differences between the embodiment shown in FIG. 15 and the embodiments described above. The same part may refer to the previous description, which will not be repeated herein.

As shown in FIG. 15, the data line 120 and the light shielding portion 80 are located in different conductive layers. For example, the light shielding portion 80 is located in the first conductive layer 21, and the data line 120 is located in the second conductive layer 22. That is to say, the light shielding portion 80 and the gate 60 of the second transistor T2 are located in a same layer, and the data line 120, the first electrode 61 of the second transistor and the second electrode 62 of the second transistor are located in a same layer.

With continued reference to FIG. 15, the display substrate may include a lap joint portion 90. The first electrode region 31 of the active layer 30 of the first transistor T1 is electrically connected to the data line 120 through the lap joint portion 90. The lap joint portion 90 may be located in the fifth conductive layer 25, that is, the lap joint portion 90 and the conductive transfer portion part 251 are located in a same layer. In this way, the lap joint portion 90 and the conductive transfer portion part 251 may be manufactured using the same patterning process, which is beneficial for reducing the number of patterning processes and the number of mask templates.

For example, in this embodiment, the lap joint portion 90 and the conductive transfer portion 251 located in the same layer are formed by transparent conductive materials. It is possible to increase the area of the effective light transmission region, thereby improving the opening rate of sub-pixel and the entire opening rate of the display panel.

FIG. 16 is a cross-sectional view of a display substrate according to some still exemplary embodiments of the present disclosure, which schematically shows a lap joint portion and a first electrode located in a same layer. It should be noted that in the following text, the differences between the embodiment shown in FIG. 16 and the embodiments described above will be mainly described. The same part may refer to the previous description, which will not be repeated herein.

It should also be noted that in FIG. 16, only a schematic cross-sectional view of a part which is located in the display region AA is shown.

As shown in FIG. 16, the light shielding portion 80 and the data line 120 are located in a same layer. For example, the light shielding portion 80 and the data line 120 are located in the first conductive layer 21 or the second conductive layer 22. For example, the gate 60 of the second transistor T2, the data line 120 and the light shielding portion 80 are located in a same layer. For example, the gate 60 of the second transistor T2, the data line 120 and the light shielding portion 80 are located in the first conductive layer 21. In this way, in the process of manufacturing the display substrate, the gate 60 of the second transistor T2, the data line 120 and light shielding portion 80 may be formed through the same patterning process, which is beneficial for reducing the number of patterning processes and the number of mask templates.

With reference to FIG. 16, the display substrate may also include: a first insulation layer IL1 disposed between the second semiconductor layer 12 and the fourth conductive layer 24; and a first via hole VH1 passing through the first insulation layer IL1. The first electrode 71 is electrically connected to the second electrode region 32 of the active layer 30 of the first transistor T1 through the first via hole VH1.

The display substrate may include a lap joint portion 90. The first electrode region 31 of the active layer 30 of the first transistor T1 is electrically connected to the data line 120 through the lap joint portion 90. The lap joint portion 90 may be located in the fourth conductive layer 24, that is, the lap joint portion 90 is located in the same layer as the first electrode 71. In this way, the lap joint portion 90 and the first electrode 71 may be manufactured by using the same patterning process, which is beneficial for reducing the number of patterning processes and the number of mask templates.

For example, in this embodiment, the lap joint portion 90 and the first electrode 71 located in the same layer are formed by transparent conductive materials. It is possible to increase the area of the effective light transmission region, thereby improving the opening rate of sub-pixel and the entire opening rate of the display panel.

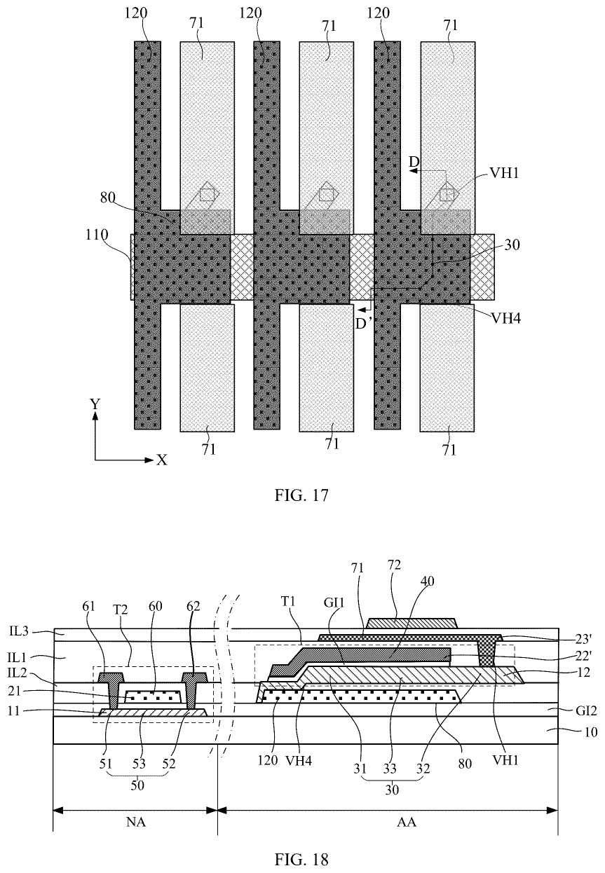

FIG. 17 is a partial enlarged view of a part of a display substrate in the display region according to some yet exemplary embodiments of the present disclosure, which schematically shows an active layer of a first transistor directly electrically connected to a data line. FIG. 18 is a cross-sectional view of a display substrate according to some exemplary embodiments of the present disclosure, in which the part located in the display region in FIG. 18 is a cross-sectional view taken along line DD′ in FIG. 17. It should be noted that in the following text, the differences between the embodiments shown in FIG. 17 and FIG. 18 and those shown in FIG. 2 to FIG. 16 will be mainly described. The same part may be referred to the previous description, which will not be repeated herein.

With reference to FIG. 17 and FIG. 18, the display substrate may include: a first semiconductor layer 11 located on the base substrate 10; a first conductive layer 21 located on a side of the first semiconductor layer 11 away from the base substrate; a second semiconductor layer 12 located on a side of the first conductive layer 21 away from the base substrate; a second conductive layer 22′ located on a side of the second semiconductor layer 12 away from the base substrate; and a third conductive layer 23′ located on a side of the base substrate away from the second conductive layer 22′.

In the embodiments shown in FIG. 17 and FIG. 18, the light shielding portion 80 and the data line 120 are located in a same layer. For example, the light shielding portion 80 and the data line 120 are located in the first conductive layer 21. That is to say, in this embodiment, the gate 60 of the second transistor T2, the data line 120 and the light shielding portion 80 are located in a same layer. For example, the gate 60 of the second transistor T2, the data line 120 and the light shielding portion 80 located in the first conductive layer 21. In this way, in a process of manufacturing the display substrate, the gate 60 of the second transistor T2, the data line 120 and the light shielding portion 80 may be formed through the same patterning process, which is beneficial for reducing the number of patterning processes and the number of mask templates.

As shown in FIG. 17, for a column of sub-pixels, a data line 120 supplies data signals to the column of sub-pixels, and the light shielding portion 80 of the column of sub-pixels is connected to the data line 120. For example, the light shielding portion 80 of the column of sub-pixels is connected to the data line 120 as a whole. The light shielding portion 80 of the column of sub-pixels may protrude along the first direction X from the data line 120. For example, in the embodiment shown in FIG. 2, the light shielding portion 80 of the column of sub-pixels may protrude to the right side along the first direction X from the data line 120. In this embodiment, the light shielding portion 80 of a column of sub-pixels is connected to a data line 120 that supplies data signals to the column of sub-pixels, which is beneficial for simplifying a structure of a mask template and reducing a difficulty of the manufacturing process.

With continued reference to FIG. 18, the display substrate may include: a second insulation layer IL2 located between the conductive layer (e.g., the first conductive layer 21) in which the data line 120 is located and the second semiconductor layer 12; and a fourth via hole VH4 passing through the second insulation layer IL2.

In this embodiment, the first electrode region 31 of the active layer of the first transistor T1 is directly in contact with the data line 120 through the fourth via hole VH4. For example, an orthographic projection of the first electrode region 31 of the active layer of the first transistor T1 at least partially overlaps with the orthographic projection of the data line 120 on the base substrate 10.

As shown in FIG. 17, an orthographic projection of the fourth via hole VH4 on the base substrate 10 at least partially overlaps with the orthographic projection of the gate line 110 on the base substrate 10. For example, for a row of sub-pixels, orthographic projections of the plurality of fourth via holes VH4 on the base substrate 10 of the row of sub-pixels at least partially overlaps with the orthographic projection of the gate line 110 supplying gate scanning signals to the row of sub-pixels on the base substrate 10. For example, the orthographic projection of the fourth via hole VH4 on the base substrate 10 falls within the orthographic projection of the gate line 110 on the base substrate 10.

In this embodiment, without disposing additional lap joint portion, the first electrode region 31 of the active layer of the first transistor T1 is directly in contact with the data line 120. By adopting such structure, with reference to FIG. 17, the size of the occupied region of the pixel driving circuit for sub-pixels in the second direction Y may be reduced, that is, the vertical pitch of the sub-pixels may be reduced, which is beneficial for achieving display substrate with such PPI.

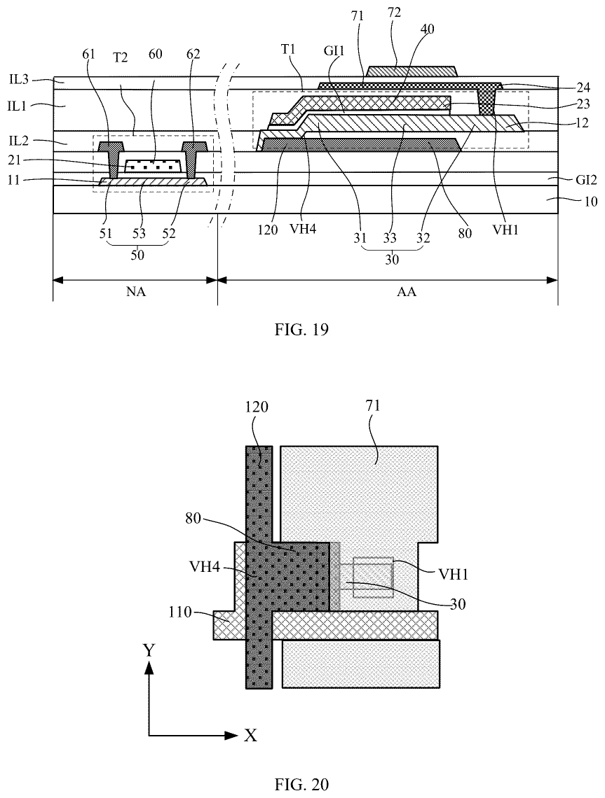

FIG. 19 is a cross-sectional view of a display substrate according to some still exemplary embodiments of the present disclosure, which schematically shows a data line and a light shielding portion located in a second conductive layer. It should be noted that in the following text, the differences between the embodiments shown in FIG. 19 and those described above will be mainly described. The same part may be referred to the previous description, which will not be repeated here.

As shown in FIG. 19, the display substrate may include: a first semiconductor layer 11 located on the base substrate 10; a first conductive layer 21 located on a side of the first semiconductor layer 11 away from the base substrate; a second conductive layer 22 located on a side of the first conductive layer 21 away from the base substrate; a second semiconductor layer 12 located on a side of the second conductive layer 22 away from the base substrate; a third conductive layer 23 located on a side of the second semiconductor layer 12 away from the base substrate; and a fourth conductive layer 24 located on a side of the third conductive layer 23 away from the base substrate.

In the embodiment shown in FIG. 19, the light shielding portion 80 and the data line 120 are located in a same layer. For example, the light shielding portion 80 and the data line 120 are located in the second conductive layer 22. That is to say, in this embodiment, the first electrode 61 of the second transistor T2 and the second electrode 62 of the second transistor T2, the data line 120 and the light shielding portion 80 are located in a same layer. For example, the first electrode 61 of the second transistor T2 and the second electrode 62 of the second transistor T2, the data line 120, and the light shielding portion 80 are located in the second conductive layer 22. In this way, in a process of manufacturing the display substrate, the first electrode 61 of the second transistor T2 and the second electrode 62 of the second transistor T2, the data line 120, and the light shielding portion 80 may be formed through the same patterning process, which is beneficial for reducing the number of patterning processes and the number of mask templates.

With continued reference to FIG. 19, the display substrate may include: a second insulation layer IL2 located between the conductive layer (e.g., the second conductive layer 22) in which the data line 120 is located and the second semiconductor layer 12; and a fourth via hole VH4 passing through the second insulation layer IL2.

In this embodiment, the first electrode region 31 of the active layer of the first transistor T1 is directly in contact the data line 120 through the fourth via hole VH4. For example, an orthographic projection of the first electrode region 31 of the active layer of the first transistor T1 at least partially overlaps with the orthographic projection of the data line 120 on the base substrate 10.

In this embodiment, without disposing additional lap joint portion, the first electrode region 31 of the active layer of the first transistor T1 is directly in contact with the data line 120. By adopting this structure, the size of the occupied region of the pixel driving circuit for sub-pixels in the second direction Y may be reduced, that is, the vertical pitch of sub-pixels may be reduced, which is beneficial for achieving display substrate with such PPI.

With reference back to FIG. 17, the first electrode 71 is electrically connected to the second electrode region 32 of the active layer 30 of the first transistor T1 through the first via hole VH1. For example, an orthographic projection of the first via hole VH1 on the base substrate 10 and an orthographic projection of the fourth via hole VH4 on the base substrate 10 are spaced apart from each other in the first direction X and the second direction Y.

FIG. 20 is a partial enlarged view of a part of a display substrate in the display region according to some still exemplary embodiments of the present disclosure. As shown in FIG. 20, the first electrode 71 is electrically connected to the second electrode region 32 of the active layer 30 of the first transistor T1 through the first via hole VH1. The first electrode region 31 of the active layer 30 of the first transistor T1 is directly in contact with the data line 120 through the fourth via hole VH4.

In this embodiment, an orthographic projection of the first via hole VH1 on the base substrate 10 is substantially aligned with an orthographic projection of the fourth via hole VH4 on the base substrate 10 in the first direction X, and they are disposed at intervals in the second direction Y. That is, a center of the orthographic projection of the first via hole VH1 on the base substrate 10 and a center of the orthographic projection of the fourth via hole VH4 on the base substrate 10 are substantially located on a same straight line extending along the first direction X.

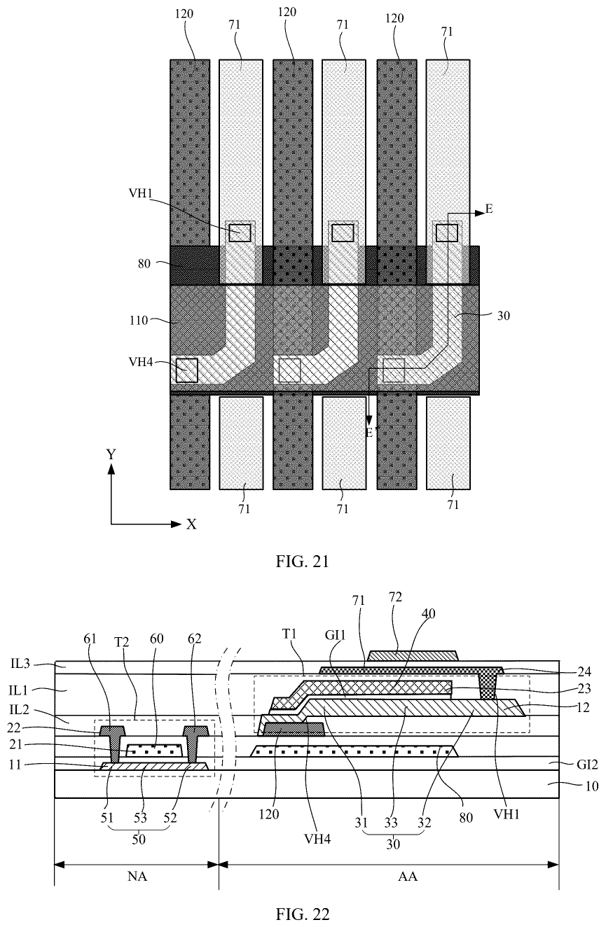

FIG. 21 is a partial enlarged view of a part of a display substrate in a display region according to some yet exemplary embodiments of the present disclosure, which schematically shows an active layer of a first transistor directly electrically connected to a data line, and the data line and a light shielding portion are located in different layers. FIG. 22 is a cross-sectional view of a display substrate according to some exemplary embodiments of the present disclosure, where the part located in the display region in FIG. 22 is a cross-sectional view taken along line EE′ in FIG. 21. It should be noted that in the following text, the differences between the embodiments shown in FIG. 21 and FIG. 22 and those shown in FIG. 2 to FIG. 20 will be mainly described. The same part may be referred to the previous description, which will not be repeated herein.

With reference to FIG. 21 and FIG. 22, the display substrate may include: a first semiconductor layer 11 located on the base substrate 10; a first conductive layer 21 located on a side of the first semiconductor layer 11 away from the base substrate; a second conductive layer 22 located on a side away from the base substrate of the first conductive layer 21; a second semiconductor layer 12 located on a side of the second conductive layer 22 away from the base substrate; a third conductive layer 23 located on a side of the second semiconductor layer 12 away from the base substrate; and a fourth conductive layer 24 located on a side of the third conductive layer 23 away from the base substrate.

As shown in FIG. 22, the data line 120 and the light shielding portion 80 are located in different conductive layers. For example, the light shielding portion 80 is located in the first conductive layer 21, and the data line 120 is located in the second conductive layer 22. That is to say, the light shielding portion 80 and the gate 60 of the second transistor T2 are located in a same layer, and the data line 120, the first electrode 61 of the second transistor and the second electrode 62 of the second transistor are located in a same layer. Similarly, in this embodiment, the data line 120 and the light shielding portion 80 are disposed in different conductive layers, and the light shielding portion 80 does not need to protrude from the data line 120 along the first direction X towards one side. In this way, it is possible to reduce the size of a single sub-pixel in the first direction X, thereby reducing the horizontal pitch of the pixel unit.

In this embodiment, the first electrode region 31 of the active layer of the first transistor T1 is directly in contact with the data line 120 through the fourth via hole VH4. For example, an orthographic projection of the first electrode region 31 of the active layer of the first transistor T1 at least partially overlaps with an orthographic projection of the data line 120 on the base substrate 10.

In this embodiment, without disposing additional lap joint portion, the first electrode region 31 of the active layer of the first transistor T1 is directly in contact with the data line 120. By adopting such structure, the size of the occupied region of the pixel driver circuit for sub-pixels in the second direction Y may be reduced, that is, the vertical pitch of the pixel units may be reduced.

Therefore, in this embodiment, it is possible to simultaneously reduce the horizontal pitch of pixel units and the vertical pitch of pixel units, which is beneficial for further improving the PPI of the display substrate.

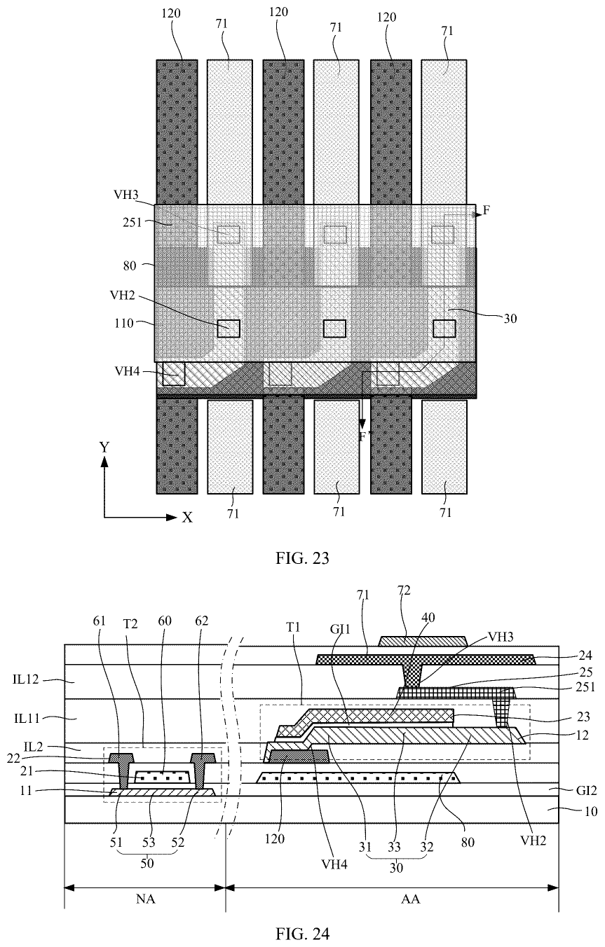

FIG. 23 is a partial enlarged view of a part of a display substrate in the display region according to some yet exemplary embodiments of the present disclosure, which schematically shows an active layer of a first transistor directly electrically connected to a data line, the data line and a light shielding portion are located in different layers, and a conductive transfer portion is provided. FIG. 24 is a cross-sectional view of a display substrate according to some exemplary embodiments of the present disclosure, where the part located in the display region in FIG. 24 is a cross-sectional view taken along line FF′ in FIG. 23. It should be noted that in the following text, the differences between the embodiments shown in FIG. 23 and FIG. 24 and those shown in FIG. 2 to FIG. 22 will be mainly described. The same part may be referred to the previous description, which will not be repeated herein.

With reference to FIG. 23 and FIG. 24, the display substrate may include: a first semiconductor layer 11 located on the base substrate 10; a first conductive layer 21 located on a side of the first semiconductor layer 11 away from the base substrate; a second conductive layer 22 located on a side away from the base substrate of the first conductive layer 21; a second semiconductor layer 12 located on a side of the second conductive layer 22 away from the base substrate; a third conductive layer 23 located on a side of the second semiconductor layer 12 away from the base substrate; and a fourth conductive layer 24 located on a side of the third conductive layer 23 away from the base substrate.

As shown in FIG. 24, the display substrate may include: a fifth conductive layer 25 disposed between the third conductive layer 23 and the fourth conductive layer 24; and a conductive transfer portion 251 located in the fifth conductive layer 25.

In the embodiments shown in FIG. 23 and FIG. 24, the first electrode 71 is electrically connected to the second electrode region 32 of the active layer of the first transistor T1 through the conductive transfer portion 251.

With continued reference to FIG. 24, the display substrate includes: a first sub-insulation layer IL11 disposed between the second semiconductor layer 12 and the fifth conductive layer 25; a second sub-insulation layer IL12 disposed between the fifth conductive layer 25 and the fourth conductive layer 24; a second via hole VH2 passing through the first sub-insulation layer IL11; and a third via hole VH3 passing through the second sub-insulation layer IL12. The first electrode 71 is electrically connected to the second electrode region 32 of the active layer of the first transistor T1 through a third via hole VH3, the conductive transfer portion 251 and a second via hole VH2.

In the embodiments of the present disclosure, an orthographic projection of the third via hole VH3 on the base substrate 10 falls into an orthographic projection of the light shielding portion 80 on the base substrate 10. That is to say, the third via hole VH3 passing through the second sub-insulation layer IL12 is located in the non-light-emitting region of the sub-pixel. In this way, the opening rate of pixel units may be improved.

In this embodiment, the data line 120 and the light shielding portion 80 are located in different conductive layers. For example, the light shielding portion 80 is located in the first conductive layer 21, and the data line 120 is located in the second conductive layer 22. That is to say, the light shielding portion 80 and the gate 60 of the second transistor T2 are located in a same layer, and the data line 120, the first electrode 61 of the second transistor and the second electrode 62 of the second transistor are located in a same layer. Similarly, in this embodiment, the data line 120 and the light shielding portion 80 are disposed in different conductive layers, and the light shielding portion 80 does not need to protrude from the data line 120 along the first direction X towards one side. In this way, it is possible to reduce the size of a single sub-pixel in the first direction X, thereby reducing the horizontal pitch of the pixel unit.

In this embodiment, the first electrode region 31 of the active layer of the first transistor T1 is directly in contact with the data line 120 through the fourth via hole VH4. For example, an orthographic projection of the first electrode region 31 of the active layer of the first transistor T1 at least partially overlaps with the orthographic projection of the data line 120 on the base substrate 10.

In this embodiment, without disposing additional lap joint portion, the first electrode region 31 of the active layer of the first transistor T1 is directly in contact with the data line 120. By adopting such structure, the size of the occupied region of the pixel driver circuit for sub-pixels in the second direction Y may be reduced, that is, the vertical pitch of the pixel units may be reduced.

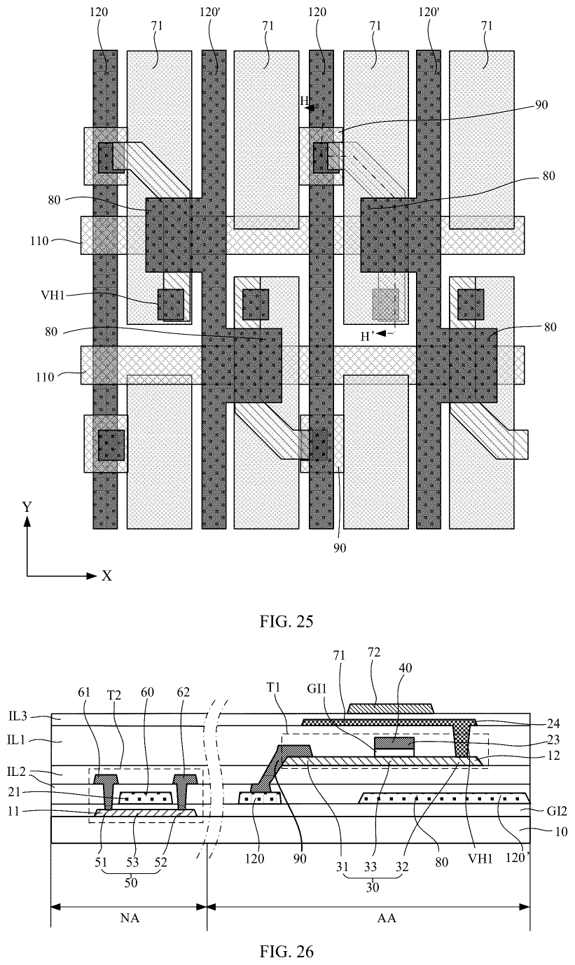

FIG. 25 is a partial enlarged view of a part of a display substrate in a display region according to some yet exemplary embodiments of the present disclosure, which schematically shows the display substrate including a data line and a dummy data line. FIG. 26 is a cross-sectional view of a display substrate according to some exemplary embodiments of the present disclosure, in which FIG. 26 is a cross-sectional view taken along line HH′ in FIG. 25. It should be noted that in the following text, the differences between the embodiments shown in FIG. 25 and FIG. 26 and those shown in FIG. 2 to FIG. 24 will be mainly described. The same part may be referred to the previous description, which will not be repeated herein.

With reference to FIG. 25 and FIG. 26, the display substrate may include a data line 120 and a dummy data line 120′ disposed on the base substrate 10. The data line 120 and the dummy data line 120′ extend along the second direction Y on the base substrate 10, and the data line 120 and the dummy data line 120′ are alternately disposed in the first direction X.

In this text, “data line” refers to a signal line that transmits data signals (such as voltage signals) and is electrically connected to the pixel driving circuit of a sub-pixel to supply the data signals to the pixel driving circuit, and “dummy data line” refers to a signal line that transmits voltage signals but is not electrically connected to the pixel driving circuit of a sub-pixel. That is to say, the data line 120 and the dummy data line 120′ transmit voltage signals. The voltage signals transmitted by the data line 120 are supplied to the pixel driving circuit to drive the pixel unit for corresponding display, while the voltage signals transmitted by the dummy data line 120′ are not supplied to the pixel driving circuit for corresponding display.

In the embodiments shown in FIG. 25 and FIG. 26, the light shielding portion 80 and the data line 120 are located in a same layer. For example, the light shielding portion 80 and the data line 120 are located in the first conductive layer 21 or the second conductive layer 22.

As shown in FIG. 25, two adjacent columns of sub-pixels share a data line 120. That is, a data line 120 supplies data signals to two adjacent columns of sub-pixels.

For example, in this embodiment, the first electrode region 31 of the active layer 30 of the first transistor T1 is electrically connected to the data line 120 through a lap joint portion 90. In the embodiments shown in FIG. 25 and FIG. 26, the lap joint portion 90 and the gate 40 of the first transistor T1 may be located in a same layer.

For two adjacent columns of sub-pixels located on two sides of a data line 120, the gates 40 of the first transistors T1 of these two adjacent columns of sub-pixels are electrically connected to the same data line 120 through their respective lap joint portions 90.

Two adjacent columns of sub-pixels share a dummy data line 120′. Specifically, for two adjacent columns of sub-pixels located on two sides of the same dummy data line 120′, the light shielding portions 80 of these two adjacent columns of sub-pixels are connected to the same dummy data line 120′.

For example, for two adjacent columns of sub-pixels located on two sides of the same dummy data line 120′, the light shielding portions 80 of the two adjacent columns of sub-pixels are connected to the same dummy data line 120′ as a whole. The light shielding portions 80 of the two adjacent columns of sub-pixels may protrude along the first direction X from the same dummy data line 120′.

For example, in the embodiment shown in FIG. 25, for two adjacent columns of sub-pixels located on two sides of the same dummy data line 120′, the light shielding portions 80 of different sub-pixels located in adjacent rows protrude from the same dummy data line 120′ along the first direction X toward different sides. For example, the light shielding portion 80 of one sub-pixel protrudes from the dummy data line 120′ toward the left side along the first direction X, and the light shielding portion 80 of another one sub-pixel protrudes from the same dummy data line 120′ to the right side along the first direction X.

In this embodiment, the light shielding portion 80 is directly connected to the dummy data line 120′ to avoid a floating state of the light shielding portion 80, which is beneficial for achieving a more stable display effect. Moreover, through a sharing method, an interval space between the light shielding portion and the dummy data line may be saved, and the horizontal pitch of the pixel unit may be reduced, which is beneficial for achieving a high PPI display substrate.

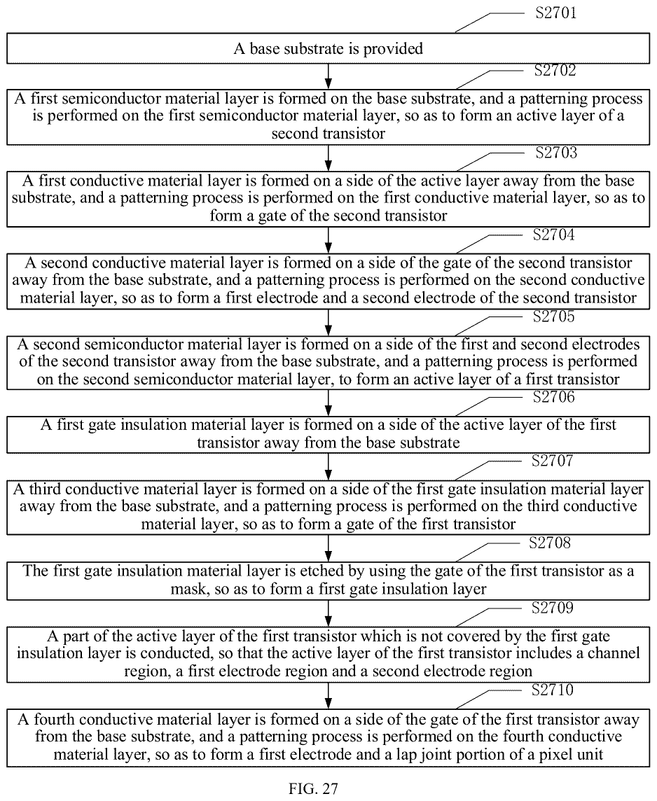

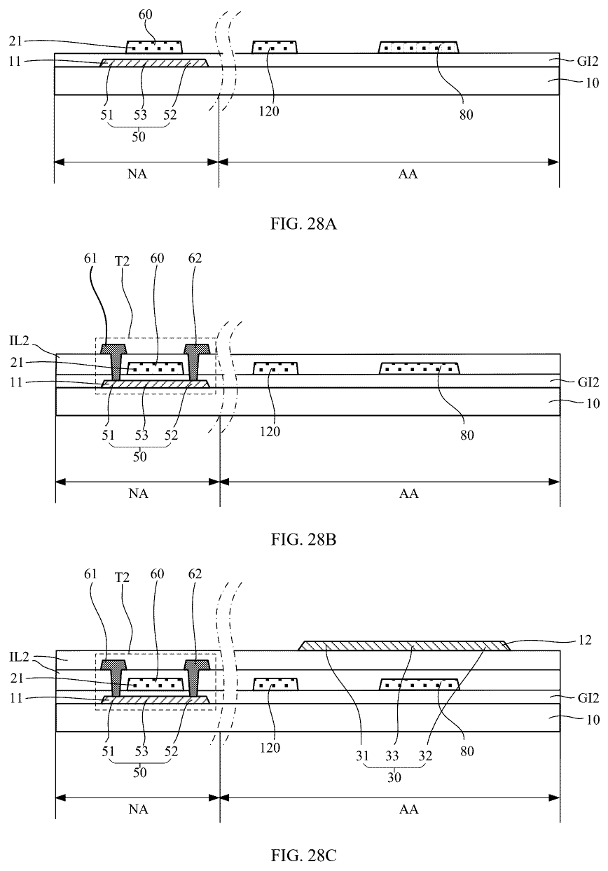

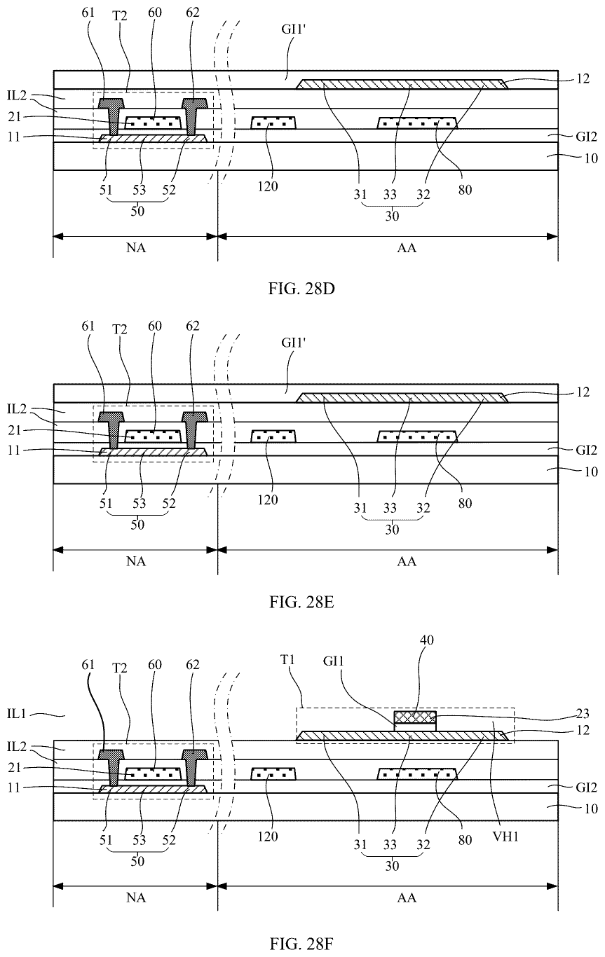

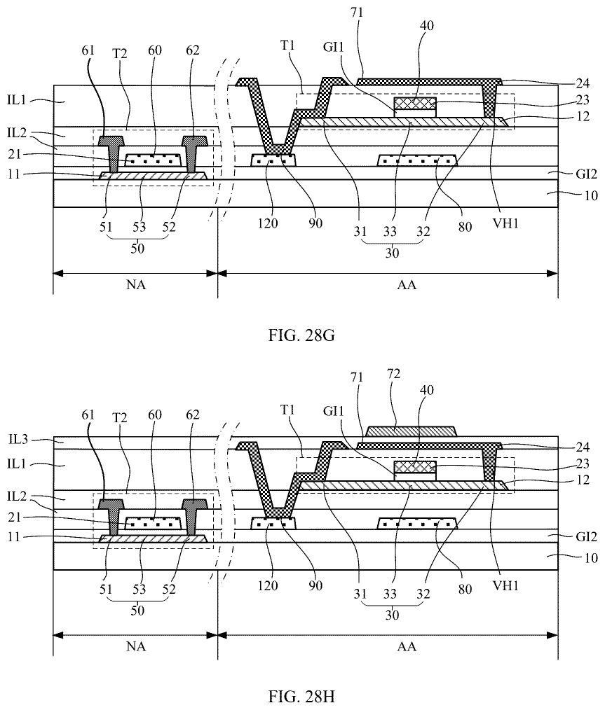

FIG. 27 schematically shows a flowchart of a method of manufacturing a display substrate according to some exemplary embodiments of the present disclosure. FIG. 28A to FIG. 28H schematically show cross-sectional views of a structure formed after some operations are performed in the method flowchart shown in FIG. 27.

With reference to FIG. 27 to FIG. 28H, the method of manufacturing the display substrate may include operations S2701 to S2710.

In operation S2701, a base substrate 10 is provided.

In operation S2702, a first semiconductor material layer is formed on the base substrate 10, and a patterning process is performed on the first semiconductor material layer, so as to form an active layer 50 of a second transistor.

In operation S2703, a first conductive material layer is formed on a side of the active layer 50 away from the base substrate, and a patterning process is performed on the first conductive material layer, so as to form a gate 60 of the second transistor.

In operation S2704, a second conductive material layer is formed on a side of the gate 60 of the second transistor away from the base substrate, and a patterning process is performed on the second conductive material layer, so as to form a first electrode 61 of the second transistor T2 and a second electrode 62 of the second transistor T2.

In operation S2705, a second semiconductor material layer is formed on a side of the first electrode 61 and second electrode 62 of the second transistor T2 away from the base substrate, and a patterning process is performed on the second semiconductor material layer, so as to form an active layer 30 of a first transistor.

In operation S2706, a first gate insulation material layer GI1′ is formed on a side of the active layer 30 of the first transistor away from the base substrate.

In operation S2707, a third conductive material layer is formed on a side of the first gate insulation material layer GI1′ away from the base substrate, and a patterning process is performed on the third conductive material layer, so as to form a gate 40 of the first transistor.

In operation S2708, the first gate insulation material layer is etched by using the gate 40 of the first transistor as a mask, so as to form a first gate insulation layer GI1.

In operation S2709, a part of the active layer 30 of the first transistor which is not covered by the first gate insulation layer GI1 is conducted, so that the active layer 30 of the first transistor includes a channel region 33, a first electrode region 31 and a second electrode region 32.

In operation S2710, a fourth conductive material layer is formed on a side of the gate 40 of the first transistor away from the base substrate, and a patterning process is performed on the fourth conductive material layer, so as to form a first electrode 71 of a pixel unit and a lap joint portion 90 of the pixel unit.

In this embodiment, the manufacturing method also includes forming a data line 120 on the base substrate 10. One of the gate 60 of the second transistor and the first electrode 61 of the second transistor is formed through the same patterning process with the data line 120. For example, the gate 60 of the second transistor, the data line 120 and the light shielding portion 80 may be formed through the same patterning process, or the first electrode 61 of the second transistor and the second electrode 62 of the second transistor, the data line 120, and the light shielding portion 80 may be formed through the same patterning process.

The first electrode region 31 of the active layer of the first transistor is electrically connected to the data line 120, and the first electrode 71 of the pixel unit is electrically connected to the second electrode region 32 of the active layer of the first transistor.

In this embodiment, the lap joint portion 90 used to electrically connect the first electrode region 31 of the active layer of the first transistor and the data line 120 is formed through the same patterning process with the first electrode 71, so that the patterning process used for drilling the first gate insulation material layer GI1′ may be eliminated, thereby simplifying the process flow and reducing the process cost.

Optionally, in this embodiment, the manufacturing method may also include forming a second electrode 72 on a side of the first electrode 71 away from the base substrate.

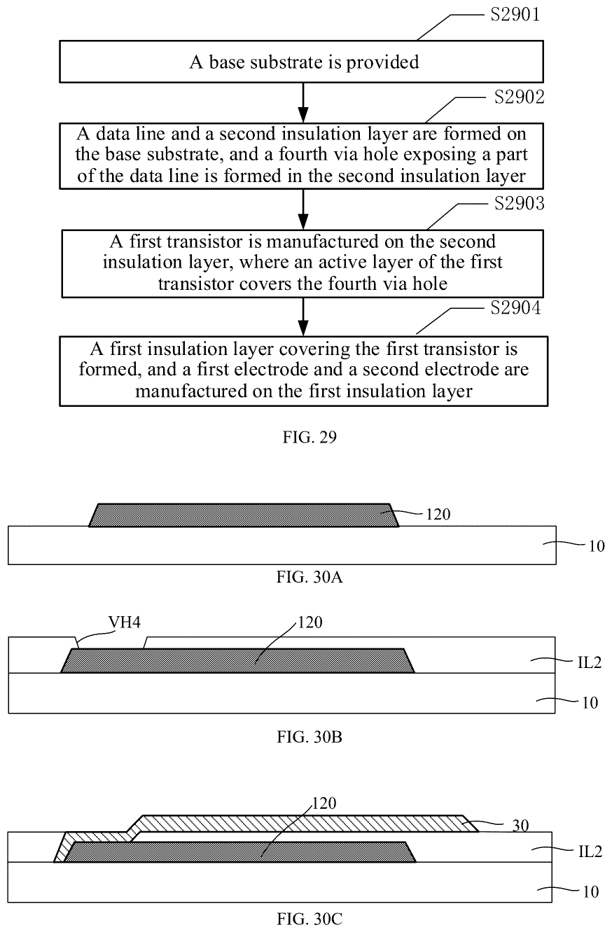

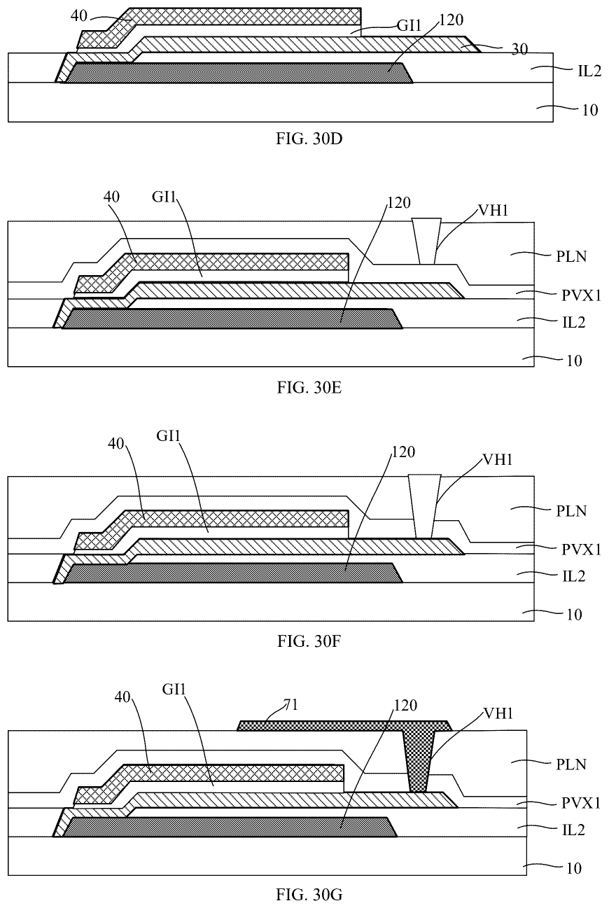

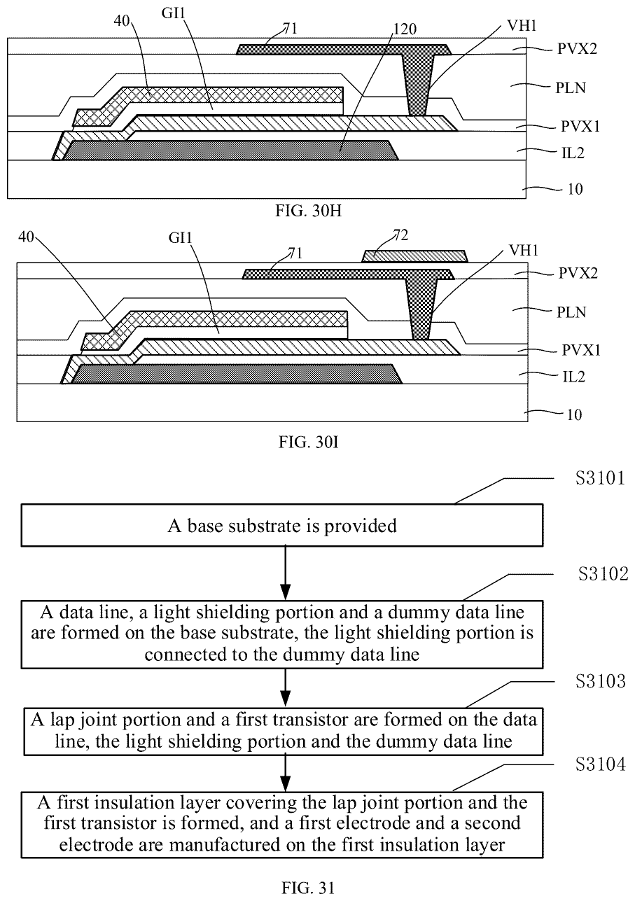

FIG. 29 schematically shows a flowchart of a method of manufacturing a display substrate according to some other exemplary embodiments of the present disclosure. FIG. 30A to FIG. 30I schematically show cross-sectional views of a structure formed after some operations are performed in the method flowchart shown in FIG. 29. It should be noted that in FIG. 30A to FIG. 30I, the partial structure of the display substrate in the display region is mainly shown.

As shown in FIG. 29, the method of manufacturing the display panel includes operations S2901 to S2904.

In operation S2901, a base substrate 10 is provided.

In operation S2902, a data line 120 and a second insulation layer IL2 are formed on the base substrate, and a fourth via hole VH4 exposing a part of the data line 120 is formed in the second insulation layer IL2.

In operation S2903, a first transistor is manufactured on the second insulation layer IL2, where an active layer 30 of the first transistor covers the fourth via hole VH4.

In operation S2904, a first insulation layer IL1 covering the first transistor is formed, and a first electrode 71 and a second electrode 72 are manufactured on the first insulation layer IL1.

With reference to FIG. 30A, after providing a base substrate 10 made of glass, a data line 120 may be manufactured on the base substrate 10, where a part of the data line 120 may serve as a light shielding metal.

With reference to FIG. 30B, a second insulation layer IL2 covering the data line 120 is formed, and a fourth via hole VH4 is formed on the second insulation layer IL2. The fourth via hole VH4 is used to achieve an electrical connection between the active layer 30 and the data line 120.

With reference to FIG. 30C, an active layer 30 is manufactured on the second insulation layer IL2, and a part of the active layer 30 covers the fourth via hole VH4.

With reference to FIG. 30D, a first gate insulation layer GI1 and a gate 40 are manufactured on the active layer 30. FIG. 30C to FIG. 30D may correspond to the structure obtained in or after the implement process of operation S2903.

With reference to FIG. 30E to FIG. 30F, a first insulation layer IL1 covering the first transistor is formed. The first insulation layer IL1 may include a first passivation layer PVX1 and a planarization layer PLN. A part of the first via hole VH1 is formed in the planarization layer PLN, and the passivation layer PVX above the active layer 30 is etched by using the planarization layer PLN as a mask, so as to form a complete first via hole VH1, which is used for subsequent electrical connection between the first electrode 71 and the active layer 30.

With reference to FIG. 30G, a first electrode 71 is formed on a side of the first insulation layer IL1 away from the base substrate. The first electrode 71 is electrically connected to the active layer 30 through the first via hole VH1.

With reference to FIG. 30H, a second passivation layer PVX2 covering the first electrode 71 is formed.

With reference to FIG. 30I, a second electrode 72 is manufactured on the second passivation layer PVX2. FIG. 30E to FIG. 30I may correspond to the structure obtained in or after the implementing process of operation S2904.

According to the embodiments of the present disclosure, by directly jointing the active layer 30 and the data line 120 through the fourth via hole VH4, the space occupied by the lap joint portion 90 is eliminated, so that the space occupied by the first transistor is smaller, so as to increase the number of pixel units per unit area, and increase the density of pixel units, thereby obtaining a high PPI display panel.

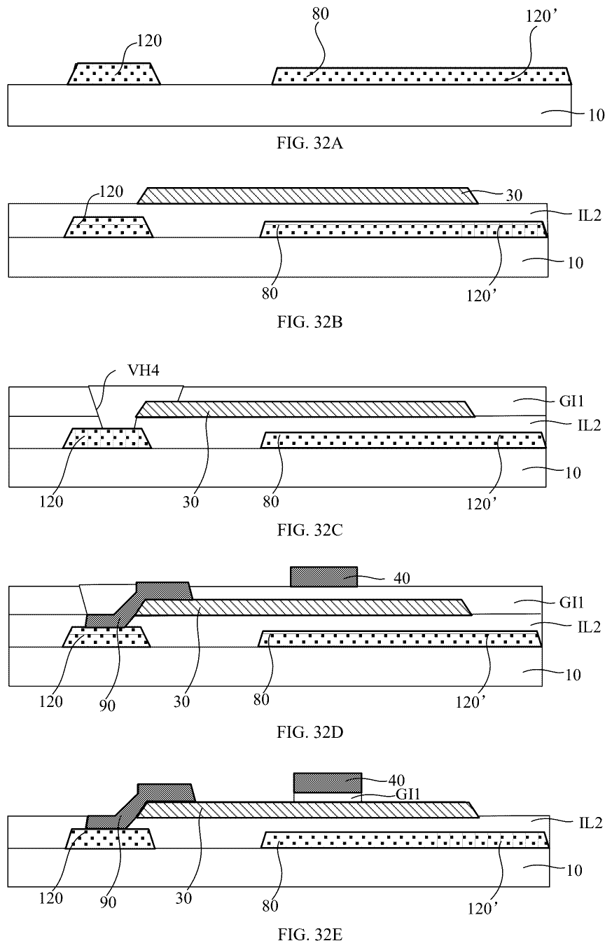

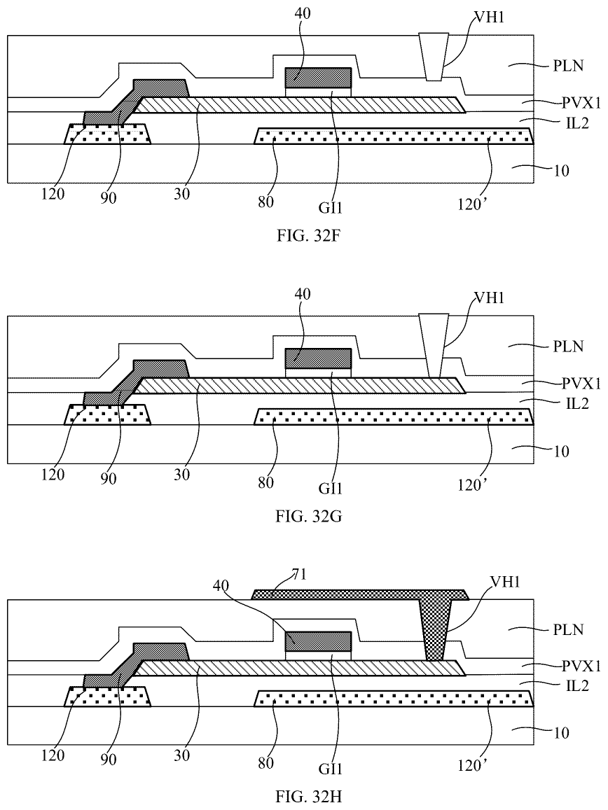

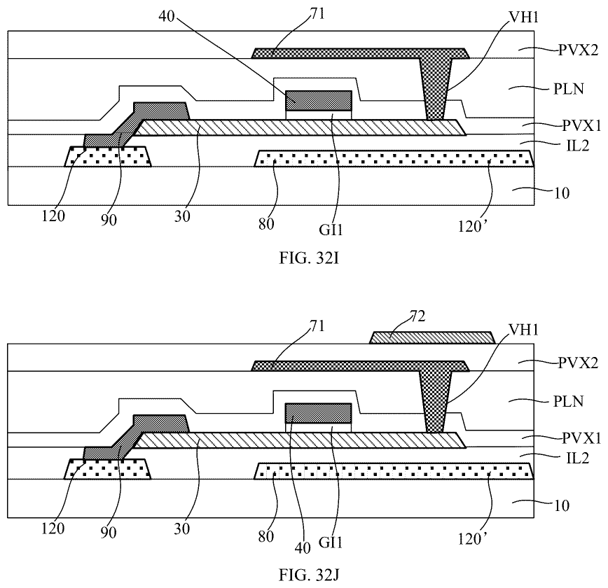

FIG. 31 schematically shows a flowchart of a method of manufacturing a display panel according to another embodiment of the present disclosure.

As shown in FIG. 31, the method of manufacturing the display panel includes operations S3101 to S3104.

In operation S3101, a base substrate 10 is provided.

In operation S3102, a data line 120, a light shielding portion 80 and a dummy data line 120′ are formed on the base substrate 10, where the light shielding portion 80 is connected to the dummy data line 120′.

In operation S3103, a lap joint portion 90 and a first transistor are formed on the data line 120, the light shielding portion 80 and the dummy data line 120′.

In operation S3104, a first insulation layer IL1 covering the lap joint portion 90 and the first transistor is formed, and a first electrode 71 and a second electrode 72 are manufactured on the first insulation layer IL1.

FIG. 32A to FIG. 32J schematically show a diagram of a structure formed after some operations are performed in the method flowchart shown in FIG. 31 according to embodiments of the present disclosure.

With reference to FIG. 32A, after providing a base substrate 10 made of glass, a data line 120, a light shielding portion 80 and a dummy data line 120′ may be manufactured on the base substrate. A part of the data line 120 may serve as a light shielding metal. The light shielding portion 80 is connected to the dummy data line layer 120′. FIG. 32A may correspond to the structure obtained in or after the implementing processes of operations S3101 to S3102.

With reference to FIG. 32B, a second insulation layer IL2 covering the data line 120, the light shielding portion 80 and the dummy data line layer 120′ is formed, and an active layer 30 is manufactured on the second insulation layer IL2.

With reference to FIG. 32C, a first gate insulation layer GI1 covering the active layer 30 is formed, and a fourth via hole VH4 is manufactured at which the first gate insulation layer GI1 is in contact with the data line 120 and the active layer 30. The fourth via hole VH4 is used for jointing the data line 120 and the active layer 30.

With reference to FIG. 32D to FIG. 32E, a gate 40 is manufactured on a second gate insulation layer GI2, and a lap joint portion 90 is manufactured at the fourth via hole VH4 by using gate metal. The first gate insulation layer GII may also be etched by using the gate 40 as a mask, and the exposed active layer 30 may be conducted. FIG. 32B to FIG. 32E may correspond to the structure obtained in or after the implementing process of operation S3103.

With reference to FIG. 32F to FIG. 32G, a first insulation layer IL1 covering the lap joint portion 90 and the first transistor is formed. The first insulation layer IL1 may include a first passivation layer PVX1 and a planarization layer PLN. A first via hole VH1 is formed in the first insulation layer IL1.

With reference to FIG. 32H, a first electrode 71 is manufactured at the first via hole VH1.

With reference to FIG. 32I, a second passivation layer PVX2 is manufactured on the first electrode 71.

With reference to FIG. 32J, a second electrode 72 is manufactured on the second passivation layer PVX2. FIG. 32F to FIG. 32J correspond to the structure obtained in or after the implementing process of operation S3104.

According to the embodiments of the present disclosure, the light shielding portion 80 is directly connected to the dummy data line 120′ to avoid the metal floating state of the light shielding portion 80 and achieve a more stable display effect. Compared to the metal of the light shielding portion 80 in a non-floating state, the horizontal pitch of the pixel unit is further reduced, thereby eliminating the space of the light shielding portion 80 and the dummy data line 120′. Therefore, smaller sized oxide transistors may be manufactured, thereby improving the PPI of the display panel.

The embodiments of the present disclosure also provide a display device. The display device may include a display substrate described in any of the above embodiments. The display device may be any product or component with display function, such as a mobile phone, a tablet, a TV, a monitor, a laptop, a digital photo frame, a navigation device, etc.

It should be understood that the display device provided in the embodiments of the present disclosure includes the above-mentioned display substrate, and the beneficial effects of the display device are the same as those of the above-mentioned display substrate, which will not be repeated herein.

Although some embodiments of the entire concept of the present disclosure have been shown and explained, those skilled in the art will understand that changes may be made to these embodiments without departing from the principles and spirit of the entire concept of the present disclosure. The scope of the present disclosure is limited by the claims and their equivalents.

1. A display substrate, comprising:
a base substrate;
a plurality of sub-pixels disposed on the base substrate, wherein the plurality of sub-pixels are arranged in an array along a first direction and a second direction on the base substrate, and at least one sub-pixel of the plurality of sub-pixels comprises a first electrode;
a first transistor and a second transistor which are disposed on the base substrate, wherein the first transistor comprises an active layer and a gate, the active layer of the first transistor comprises a channel region, a first electrode region and a second electrode region, and the second transistor comprises an active layer, a gate, a first electrode and a second electrode; and
a data line disposed on the base substrate, wherein the data line extends in the second direction on the base substrate,
wherein the display substrate comprises:
a first semiconductor layer located on the base substrate;
a first conductive layer located on a side of the first semiconductor layer away from the base substrate;
a second conductive layer located on a side of the first conductive layer away from the base substrate;
a second semiconductor layer located on a side of the second conductive layer away from the base substrate;
a third conductive layer located on a side of the second semiconductor layer away from the base substrate; and
a fourth conductive layer located on a side of the third conductive layer away from the base substrate;
wherein the active layer of the second transistor is located in the first semiconductor layer, the gate of the second transistor is located in the first conductive layer, and the first electrode of the second transistor and the second electrode of the second transistor are located in the second conductive layer; the active layer of the first transistor is located in the second semiconductor layer, and the gate of the first transistor is located in the third conductive layer; and the first electrode of the at least one sub-pixel is located in the fourth conductive layer; and
wherein the data line is located in one of the first conductive layer and the second conductive layer, the first electrode region of the active layer of the first transistor is electrically connected to the data line, and the first electrode of the at least one sub-pixel is electrically connected to the second electrode region of the active layer of the first transistor.

2. The display substrate of claim 1, wherein the display substrate further comprises a light shielding portion, wherein an orthographic projection of the light shielding portion on the base substrate at least partially overlaps with the channel region of the active layer of the first transistor, and the light shielding portion is located in one of the first conductive layer and the second conductive layer.

3. The display substrate of claim 2, wherein the data line and the light shielding portion are located in different conductive layers.

4. The display substrate of claim 3, wherein the orthographic projection of the light shielding portion on the base substrate partially overlaps with an orthographic projection of the data line on the base substrate.

5. The display substrate of claim 4, wherein a plurality of light shielding portions of a row of sub-pixels arranged along the first direction are connected to each other, to form a light shielding strip extending along the first direction, and an orthographic projection of the light shielding strip on the base substrate intersects with the orthographic projection of the data line on the base substrate.

6. The display substrate of claim 2, wherein the data line and the light shielding portion are located in a same conductive layer.

7. The display substrate of claim 6, wherein the light shielding portion is connected to the data line, and the light shielding portion protrudes along the first direction from the data line.

8. The display substrate of claim 6, wherein
the display substrate further comprises a dummy data line disposed on the base substrate, the dummy data line extends along the second direction on the base substrate, and the data line and the dummy data line are alternately disposed in the first direction; and
the light shielding portion is connected to the dummy data line, and the light shielding portion protrudes along the first direction from the dummy data line.

9. The display substrate of claim 8, wherein
two adjacent columns of sub-pixels share the dummy data line; and
the two adjacent columns of sub-pixels are located on opposite sides of the dummy data line, and light shielding portions of the two adjacent columns of sub-pixels are connected to the dummy data line.

10. The display substrate of claim 1, wherein the first electrode region of the active layer of the first transistor is electrically connected to the data line through a lap joint portion.

11. The display substrate of claim 10, wherein the lap joint portion is located in the third conductive layer.

12. The display substrate of claim 11, wherein
the display substrate further comprises a gate line disposed on the base substrate, the gate line extends in the first direction, and an orthographic projection of a part of the gate line on the base substrate overlaps with an orthographic projection of the active layer of the first transistor on the base substrate, so as to form the gate of the first transistor; and
an orthographic projection of the lap joint portion on the base substrate and an orthographic projection of the gate line on the base substrate are spaced apart from each other in the second direction.

13. The display substrate of claim 10, wherein the lap joint portion comprises a transparent conductive material.

14. The display substrate of claim 1, wherein:
the display substrate comprises:
a first insulation layer disposed between the second semiconductor layer and the fourth conductive layer; and
a first via hole passing through the first insulation layer;
the first electrode of the sub-pixel is electrically connected to the second electrode region of the active layer of the first transistor through the first via hole;
the first electrode region of the active layer of the first transistor is electrically connected to the data line through a lap joint portion; and
the lap joint portion and the first electrode of the at least one sub-pixel are located in the fourth conductive layer, and the first electrode of the at least one sub-pixel comprises a transparent conductive material.

15. The display substrate of claim 1, wherein:
the display substrate comprises:
a fifth conductive layer disposed between the third conductive layer and the fourth conductive layer; and
a conductive transfer portion located in the fifth conductive layer;
the first electrode of the at least one sub-pixel is electrically connected to the second electrode region of the active layer of the first transistor through the conductive transfer portion,
the display substrate further comprises:
a first sub-insulation layer disposed between the second semiconductor layer and the fifth conductive layer;
a second sub-insulation layer disposed between the fifth conductive layer and the fourth conductive layer;
a second via hole passing through the first sub-insulation layer; and
a third via hole passing through the second sub-insulation layer;
the first electrode of the at least one sub-pixel is electrically connected to the second electrode region of the active layer of the first transistor through the third via hole, the conductive transfer portion and the second via hole;
an orthographic projection of the third via hole on the base substrate falls within the orthographic projection of the light shielding portion on the base substrate;
the orthographic projection of the second via hole on the base substrate and the orthographic projection of the third via hole on the base substrate are spaced apart from each other;
the first electrode region of the active layer of the first transistor is electrically connected to the data line through a lap joint portion;
the lap joint portion and the conductive transfer portion are located in the fifth conductive layer; and
the lap joint portion and the first electrode of the at least one sub-pixel are located in the fourth conductive layer.

16-20. (canceled)

21. The display substrate of claim 1, wherein:
the display substrate comprises:
a second insulation layer located between a conductive layer in which the data line is located and the second semiconductor layer; and
a fourth via hole passing through the second insulation layer; and
the first electrode region of the active layer of the first transistor is directly in contact with the data line through the fourth via hole;
the display substrate further comprises a gate line disposed on the base substrate, the gate line extends in the first direction, and an orthographic projection of a part of the gate line on the base substrate overlaps with an orthographic projection of the active layer of the first transistor on the base substrate;
an orthographic projection of the fourth via hole on the base substrate at least partially overlaps with an orthographic projection of the gate line on the base substrate;
the active layer of the first transistor comprises a metal oxide semiconductor material; and/or, the active layer of the second transistor comprises a low temperature poly-silicon semiconductor material; and
the at least one sub-pixel further comprises a second electrode, the first electrode of the at least one sub-pixel is one of a pixel electrode or a common electrode, and the second electrode of the at least one sub-pixel is the other of the pixel electrode or the common electrode.

22-26. (canceled)

27. A display substrate, comprising:
a base substrate;
a plurality of sub-pixels disposed on the base substrate, wherein the plurality of sub-pixels are arranged in an array along a first direction and a second direction on the base substrate, and at least one sub-pixel of the plurality of sub-pixels comprises a first electrode;
a first transistor and a second transistor which are disposed on the base substrate, wherein the first transistor comprises an active layer and a gate, the active layer of the first transistor comprises a channel region, a first electrode region and a second electrode region, and the second transistor comprises an active layer, a gate, a first electrode and a second electrode; and
a data line disposed on the base substrate, wherein the data line extends along the second direction on the base substrate,
wherein the display substrate comprises:
a first semiconductor layer located on the base substrate;
a first conductive layer located on a side of the first semiconductor layer away from the base substrate;
a second semiconductor layer located on a side of the first conductive layer away from the base substrate;
a second conductive layer located on a side of the second semiconductor layer away from the base substrate; and
a third conductive layer located on a side of the second conductive layer away from the base substrate;
wherein the active layer of the second transistor is located in the first semiconductor layer, the gate of the second transistor is located in the first conductive layer, and the first electrode of the second transistor and the second electrode of the second transistor are located in the second conductive layer; the active layer of the first transistor is located in the second semiconductor layer, and the gate of the first transistor is located in the second conductive layer; and
the first electrode of the at least one sub-pixel is located in the third conductive layer; and
wherein the data line is located in the first conductive layer, the first electrode region of the active layer of the first transistor is electrically connected to the data line, and the first electrode of the at least one sub-pixel is electrically connected to the second electrode region of the active layer of the first transistor.

28. The display substrate of claim 27, wherein the display substrate further comprises a light shielding portion, wherein an orthographic projection of the light shielding portion on the base substrate at least partially overlaps with the channel region of the active layer of the first transistor, and the light shielding portion and the data line are located in the first conductive layer, and
wherein the light shielding portion is connected to the data line, and the light shielding portion protrudes along the first direction from the data line.

29. (canceled)

30. A display device comprising the display substrate of claim 1.

31. A method for manufacturing a display substrate, comprising:
providing a base substrate;
forming a first semiconductor material layer on the base substrate, and performing a patterning process on the first semiconductor material layer, so as to form an active layer of a second transistor;
forming a first conductive material layer on a side of the active layer of the second transistor away from the base substrate, and performing a patterning process on the first conductive material layer, so as to form a gate of the second transistor;
forming a second conductive material layer on a side of the gate of the second transistor away from the base substrate, and performing a patterning process on the second conductive material layer, so as to form a first electrode of the second transistor and a second electrode of the second transistor;
forming a second semiconductor material layer on a side of the first electrode and second electrode of the second transistor away from the base substrate, and performing a patterning process on the second semiconductor material layer, so as to form an active layer of a first transistor;
forming a first gate insulation material layer on a side of the active layer of the first transistor away from the base substrate;
forming a third conductive material layer on a side of the first gate insulation material layer away from the base substrate, and performing a patterning process on the third conductive material layer, so as to form a gate of the first transistor;
etching the first gate insulation material layer by using the gate of the first transistor as a mask, so as to form a first gate insulation layer;
conducting a part of the active layer of the first transistor which is not covered by the first gate insulation layer, so that the active layer of the first transistor comprises a channel region, a first electrode region and a second electrode region; and
forming a fourth conductive material layer on a side of the gate of the first transistor away from the base substrate, and performing a patterning process on the fourth conductive material layer, so as to form a first electrode of the a sub-pixel and a lap joint portion of the sub-pixel,
wherein the manufacturing method further comprises forming a data line on the base substrate, one of the gate of the second transistor and the first electrode of the second transistor is formed through a same patterning process with the data line; and
wherein the first electrode region of the active layer of the first transistor is electrically connected to the data line, and the first electrode of the sub-pixel is electrically connected to the second electrode region of the active layer of the first transistor.
